(19) United States
(12) Patent Application Publication
(10) Pub. No.: US 2010/0167482 A1
(43) Pub. Date: Jul. 1, 2010

(54) SEMICONDUCTOR DEVICE MANUFACTURING METHOD

(76) Inventors: Shinji MORI, Yokohama-Shi (JP); Masahiko Murano, Kawasaki-Shi (JP); Ichiro Mizushima, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/646,097

(22) Filed: Dec. 23, 2009

(30) Foreign Application Priority Data
Dec. 26, 2008 (JP) 2008-334189

(51) Int. Cl. H01L 21/336

(52) U.S. Cl. 438/285; 257/E21.409

(57) ABSTRACT

There is provided a method of manufacturing a semiconductor device that allows the threshold voltage of a p-type MOSFET to be controlled with accuracy as high as possible in a multi-oxide process.

The method forms two types of field-effect transistors including gate insulating films having different film thickness in a first region and a second region on a silicon substrate, respectively, and includes forming a silicon-germanium film (Si₁₋ₓGeₓ, 0<x<1) in each of the first and second regions, forming a first gate insulating film on the silicon-germanium film in the first and second regions, removing the first gate insulating film in the first region, forming a protective film for the silicon-germanium film on the silicon-germanium film formed in the first region, and forming a second gate insulating film comprising a high-k film on the protective film in the first region and the first gate insulating film in the second region.

### CROSS-REFERENCE TO RELATED APPLICATION

This application is based upon and claims the benefit of priority from prior Japanese Patent Application No. 2008-334189, filed on Dec. 26, 2008, the entire content of which are incorporated herein by reference.

### BACKGROUND OF THE INVENTION

1. Field of the Invention

The present invention relates to a method of manufacturing a semiconductor device, and more particularly to a method of manufacturing a metal oxide semiconductor (MOS) transistor having a SiGe channel.

2. Related Art

Recently, as the miniaturization of a field-effect transistor (hereinafter, referred to also as a “MOSFET”) proceeds, the reduction of the thickness of a gate insulating film proceeds. Because of this thickness reduction, problems such as increase in leakage current have arisen. With gate insulating films that are extension of conventional techniques, their limits in terms of thickness reduction have become visible. Therefore, gate insulating films are moving from conventional gate insulating films made of silicon oxide films (SiO₂) or silicon oxynitride films (SiON) to gate insulating films having dielectric constants higher than those of the conventional insulating films (hereinafter, referred to as “high-k films”). Used as materials for the high-k films are, for example, hafnium oxides such as hafnium silicon oxynitride (HfSiON) and hafnium oxide (HfO₂).

In the case of a conventional gate structure in which a gate electrode of polycrystalline silicon (Poly Si) and a high-k film are combined, however, a problem of depletion of the gate electrode arises. The advantage due to the thickness reduction of a gate insulating film therefore decreases. To avoid the depletion of a gate electrode, the material for the gate electrode is moving from polycrystalline silicon to metal.

However, one problem with the gate structure of combining a high-k film and a metal gate electrode is that the controllability of the threshold voltage deteriorates. As one technology of solving this problem, there is channel SiGe technology (C-SiGe) that introduces a SiGe film into a channel portion. In the channel SiGe technology, a SiGe film having a desired Ge concentration is provided directly under a gate insulating film. By varying the Ge concentration in this SiGe film, the work function of SiGe varies. This causes the difference between the work function of the SiGe film and the work function of the metal gate electrode to be varied, thereby enabling control of the threshold voltage.

Note that a MOSFET having a high-k film as a gate insulating film, a metal gate electrode as a gate electrode, and a SiGe film as a channel has been disclosed, for example in Japanese Patent Application Laid-Open No. 2007-13025.

### SUMMARY OF THE INVENTION

According to a first aspect of the invention, there is provided a method of manufacturing a semiconductor device in which two types of field-effect transistors that include gate insulating films having different film thickness are formed in a first region and a second region on a silicon substrate, respectively, and that includes the following.

A silicon-germanium film (Si₁₋ₓGeₓ, 0<x<1) is formed in each of the first region and the second region; a first gate insulating film is formed on the silicon-germanium film in the first region and the second region; the first gate insulating film in the first region is removed; a protective film for the silicon-germanium film is formed on the silicon-germanium film formed in the first region; and a second gate insulating film comprising a high-k film is formed on the protective film in the first region and on the first gate insulating film in the second region.

According to a second aspect of the invention, there is provided a method of manufacturing a semiconductor device in which three types of field-effect transistors that include gate insulating films having different film thickness are formed in a first region, a second region and a third region on a silicon substrate, respectively, and that includes the following.

A silicon-germanium film (Si₁₋ₓGeₓ, 0<x<1) is formed in each of the first region, the second region and the third region; a first gate insulating film is formed on the silicon-germanium film in the first region, the second region and the third region; the first gate insulating film in the second region is removed; a second gate insulating film is formed on the first gate insulating film in the first region and the third region and on the silicon-germanium film in the second region; the first gate insulating film and the second gate insulating film in the first region are removed; a protective film for the silicon-germanium film is formed on the silicon-germanium film in the first region; a third gate insulating film comprising a high-k film is formed on the protective film in the first region and on the second gate insulating film in the second region and the third region; and a metal layer is formed on the third gate insulating film in the first region, the second region and the third region.

According to a third aspect of the invention, there is provided a method of manufacturing a semiconductor device in which two types of field-effect transistors that include gate insulating films having different film thickness are formed in a first region and a second region on a silicon substrate, respectively, and that includes the following.

A first gate insulating film is formed in the first region and the second region; the first gate insulating film in the first region is removed; a silicon-germanium film (Si₁₋ₓGeₓ, 0<x<1) and a protective film for the silicon-germanium film on the silicon-germanium film are successively formed in the first region; and a second gate insulating film comprising a high-k film is formed on the protective film in the first region and on the first gate insulating film in the second region.

According to a fourth aspect of the invention, there is provided a method of manufacturing a semiconductor device in which three types of field-effect transistors that include gate insulating films having different film thickness are formed in a first region, a second region and a third region on a silicon substrate, respectively, and that includes the following.

A first gate insulating film is formed in the first region, the second region and the third region; the first gate insulating film in the second region is removed; a second gate insulating film is formed on the first gate insulating film in the first region and the third region, and in the second region; the first gate insulating film and the second gate insulating film in the first region are removed; a silicon-germanium film (Si₁₋ₓGeₓ, 0<x<1) and a protective film for the silicon-germanium film on the silicon-germanium film are successively formed in the first region; a third gate insulating film comprising a high-k film is formed on the protective film in the first region and on the second gate insulating film in the second region and the third region; and a metal layer is formed on the third gate insulating film in the first region, the second region and the third region.

### BRIEF DESCRIPTION OF THE DRAWINGS

FIG. 1A is a cross-sectional process view illustrating a method of manufacturing a semiconductor device according to a first embodiment;

FIG. 1B is a cross-sectional process view following FIG. 1A, illustrating the method of manufacturing a semiconductor device according to the first embodiment;

FIG. 1C is a cross-sectional process view following FIG. 1B, illustrating the method of manufacturing a semiconductor device according to the first embodiment;

FIG. 1D is a cross-sectional process view following FIG. 1C, illustrating the method of manufacturing a semiconductor device according to the first embodiment;

FIG. 1E is a cross-sectional process view following FIG. 1D, illustrating the method of manufacturing a semiconductor device according to the first embodiment;

FIG. 1F is a cross-sectional process view following FIG. 1E, illustrating the method of manufacturing a semiconductor device according to the first embodiment;

FIG. 1G is a cross-sectional process view following FIG. 1F, illustrating the method of manufacturing a semiconductor device according to the first embodiment;

FIG. 1H is a cross-sectional process view following FIG. 1G, illustrating the method of manufacturing a semiconductor device according to the first embodiment;

FIG. 1I is a cross-sectional process view following FIG. 1H, illustrating the method of manufacturing a semiconductor device according to the first embodiment;

FIG. 1J is a cross-sectional process view following FIG. 1I, illustrating the method of manufacturing a semiconductor device according to the first embodiment;

FIG. 1K is a cross-sectional process view following FIG. 1J, illustrating the method of manufacturing a semiconductor device according to the first embodiment;

FIG. 1L is a cross-sectional process view following FIG. 1K, illustrating the method of manufacturing a semiconductor device according to the first embodiment;

FIG. 1M is a cross-sectional process view following FIG. 1L, illustrating the method of manufacturing a semiconductor device according to the first embodiment;

FIG. 1N is a cross-sectional process view following FIG. 1M, illustrating the method of manufacturing a semiconductor device according to the first embodiment;

FIG. 1O is a cross-sectional process view following FIG. 1N, illustrating the method of manufacturing a semiconductor device according to the first embodiment;

FIG. 2A is a cross-sectional process view illustrating a method of manufacturing a semiconductor device according to a second embodiment;

FIG. 2B is a cross-sectional process view following FIG. 2A, illustrating the method of manufacturing a semiconductor device according to the second embodiment;

FIG. 2C is a cross-sectional process view following FIG. 2B, illustrating the method of manufacturing a semiconductor device according to the second embodiment;

FIG. 2D is a cross-sectional process view following FIG. 2C, illustrating the method of manufacturing a semiconductor device according to the second embodiment;

FIG. 3A is a cross-sectional process view illustrating a method of manufacturing a semiconductor device according to a third embodiment;

FIG. 3B is a cross-sectional process view following FIG. 3A, illustrating the method of manufacturing a semiconductor device according to the third embodiment;

FIG. 3C is a cross-sectional process view following FIG. 3B, illustrating the method of manufacturing a semiconductor device according to the third embodiment;

FIG. 3D is a cross-sectional process view following FIG. 3C, illustrating the method of manufacturing a semiconductor device according to the third embodiment;

FIG. 3E is a cross-sectional process view following FIG. 3D, illustrating the method of manufacturing a semiconductor device according to the third embodiment;

FIG. 3F is a cross-sectional process view following FIG. 3E, illustrating the method of manufacturing a semiconductor device according to the third embodiment;

FIG. 3G is a cross-sectional process view following FIG. 3F, illustrating the method of manufacturing a semiconductor device according to the third embodiment;

FIG. 3H is a cross-sectional process view following FIG. 3G, illustrating the method of manufacturing a semiconductor device according to the third embodiment;

FIG. 3I is a cross-sectional process view following FIG. 3H, illustrating the method of manufacturing a semiconductor device according to the third embodiment;

FIG. 3J is a cross-sectional process view following FIG. 3I, illustrating the method of manufacturing a semiconductor device according to the third embodiment;

FIG. 4A is a cross-sectional process view illustrating a method of manufacturing a semiconductor device according to a fourth embodiment;

FIG. 4B is a cross-sectional process view following FIG. 4A, illustrating the method of manufacturing a semiconductor device according to the fourth embodiment;

FIG. 4C is a cross-sectional process view following FIG. 4B, illustrating the method of manufacturing a semiconductor device according to the fourth embodiment;

FIG. 4D is a cross-sectional process view following FIG. 4C, illustrating the method of manufacturing a semiconductor device according to the fourth embodiment;

FIG. 4E is a cross-sectional process view following FIG. 4D, illustrating the method of manufacturing a semiconductor device according to the fourth embodiment;

FIG. 4F is a cross-sectional process view following FIG. 4E, illustrating the method of manufacturing a semiconductor device according to the fourth embodiment;

FIG. 4G is a cross-sectional process view following FIG. 4F, illustrating the method of manufacturing a semiconductor device according to the fourth embodiment;

FIG. 5A is a cross-sectional process view illustrating a method of manufacturing a semiconductor device according to a comparative example;

FIG. 5B is a cross-sectional process view following FIG. 5A, illustrating the method of manufacturing a semiconductor device according to the comparative example;

FIG. 5C is a cross-sectional process view following FIG. 5B, illustrating the method of manufacturing a semiconductor device according to the comparative example;

FIG. 5D is a cross-sectional process view following FIG. 5C, illustrating the method of manufacturing a semiconductor device according to the comparative example;

FIG. 5E is a cross-sectional process view following FIG. 5D, illustrating the method of manufacturing a semiconductor device according to the comparative example;

FIG. 5F is a cross-sectional process view following FIG. 5E, illustrating the method of manufacturing a semiconductor device according to the comparative example;

FIG. 5G is a cross-sectional process view following FIG. 5F, illustrating the method of manufacturing a semiconductor device according to the comparative example;

FIG. 5H is a cross-sectional process view following FIG. 5G, illustrating the method of manufacturing a semiconductor device according to the comparative example;

FIG. 5I is a cross-sectional process view following FIG. 5H, illustrating the method of manufacturing a semiconductor device according to the comparative example; and

FIG. 5J is a cross-sectional process view following FIG. 5I, illustrating the method of manufacturing a semiconductor device according to the comparative example.

### DESCRIPTION OF THE EMBODIMENTS

Before description of embodiments of the invention, the circumstances in which the inventors have accomplished the invention will be described.

As described above, the channel SiGe technology is excellent in control of the threshold voltage; however, it has the following problems. That is, to form a gate insulating film on a SiGe film, after the surface of the SiGe film is oxidized, the gate insulating film is formed on the resultant oxide. Therefore, the interface between the SiGe film and the gate insulating film deteriorates to form a deep level in high concentration at the interface. As a result, variations in threshold voltage among MOSFETs occur, reducing the controllability of the threshold voltage. Moreover, a problem of decrease in carrier mobility occurs.

As one of measures against the above problems, it is conceivable to form a very thin silicon film as a cap layer, that is, a protective film on a SiGe film, and then form a gate insulating film. In this case, the surface of the silicon film is oxidized to be a silicon oxide film (SiO₂), and the gate insulating film is formed on the silicon oxide film. During the process of forming the gate insulating film, oxidation proceeds from the surface of this silicon film toward the inside. The silicon oxide film becomes part of the gate insulating film.

Consequently, if a sufficiently thick silicon film is formed on the SiGe film, no damage to the SiGe film occurs during the process of forming the gate insulating film. The interface between the SiGe film and the gate insulating film therefore does not deteriorate. Accordingly, such a problem of reduction in controllability of the threshold voltage as mentioned above does not occur.

Incidentally, used in an actual process of fabricating a large scaled integrated circuit (LSI) is a multi-oxide process of forming, on a single semiconductor substrate, a plurality of types of MOSFETs whose gate insulating films having different thickness.

By varying the film thicknesses of gate insulating films, MOSFETs that differ in operating voltage can be obtained. For example, it is considered that three types of MOSFETs that include gate insulating films having different film thickness are formed on a semiconductor substrate by this multi-oxide process.

Hereinbelow, it is assumed that a region in which a MOSFET having the thinnest gate insulating film is formed is referred to as a “low voltage (LV) region”, a region in which a MOSFET having the thinnest film next to the MOSFET in the LV region is formed is referred to as a “medium voltage (MV) region”, and a region in which a MOSFET having the thickest gate insulating film is formed is referred to as a “high voltage (HV) region”.

The MOSFET in the LV region is suitable for low power consumption and high-speed operation. The MOSFET in the LV region has the smallest operating voltage, and therefore the threshold voltage of this MOSFET often needs to be controlled at high accuracy as compared to those in other regions.

On the other hand, the MOSFET in the MV region is suitable for applications in which the operating voltage and the drive current are large. Based on such characteristics of the MOSFETs, the HV region includes, for example, an interface unit with an outer circuit, and the LV region includes, for example, a core unit of an LSI.

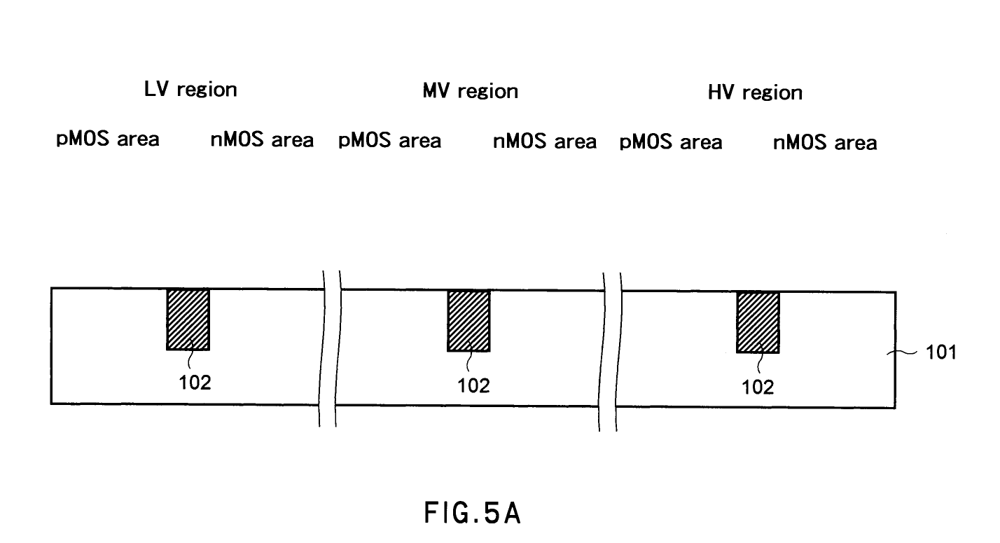

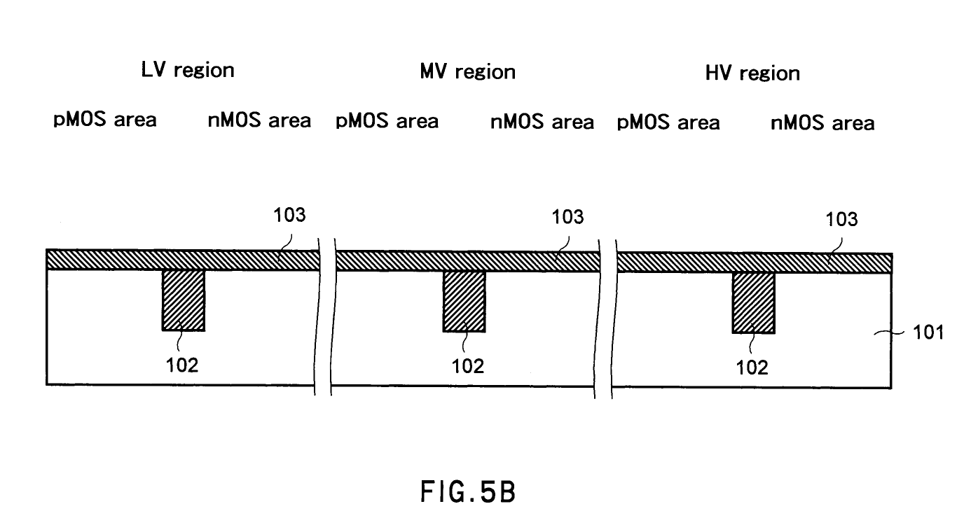

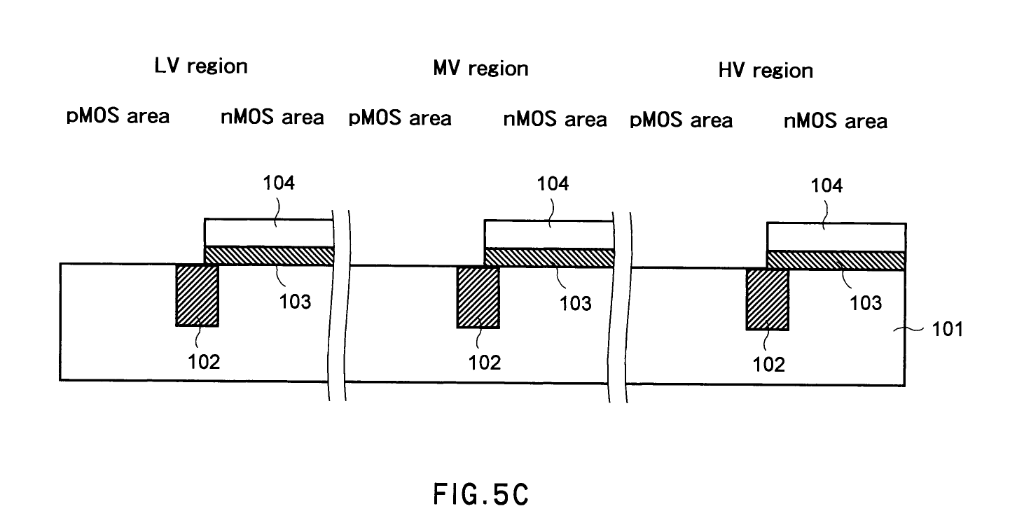

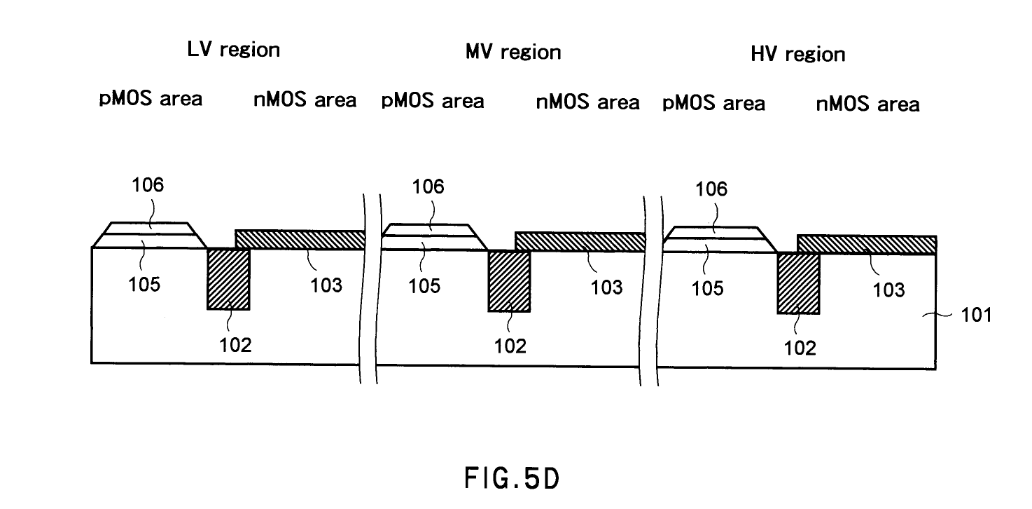

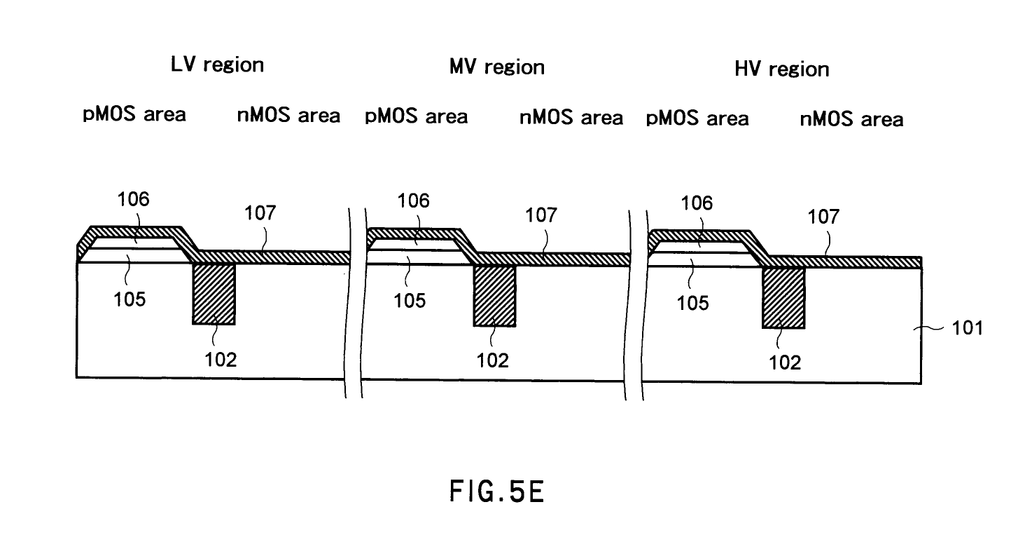

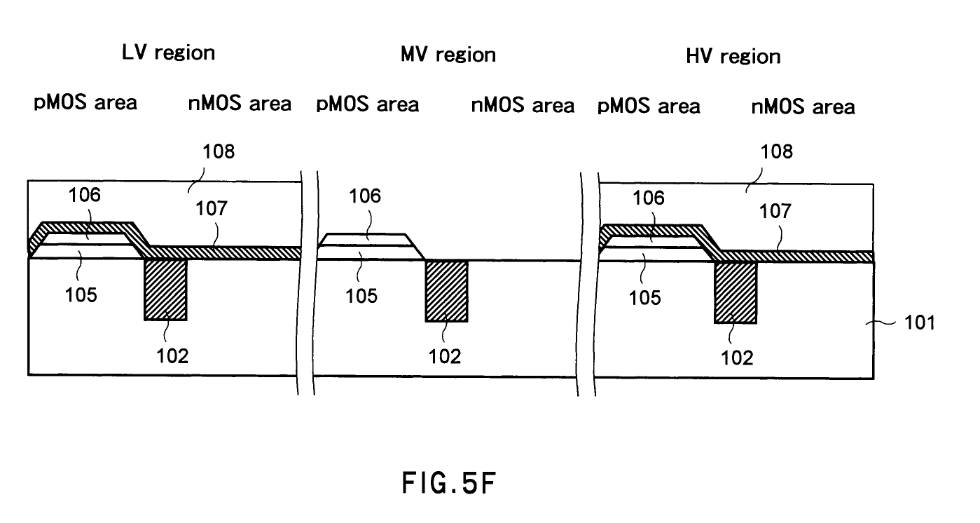

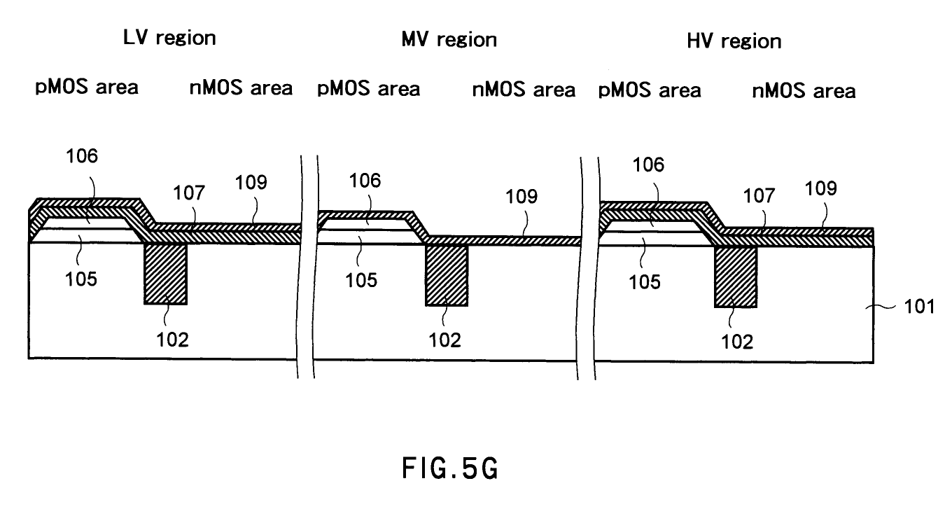

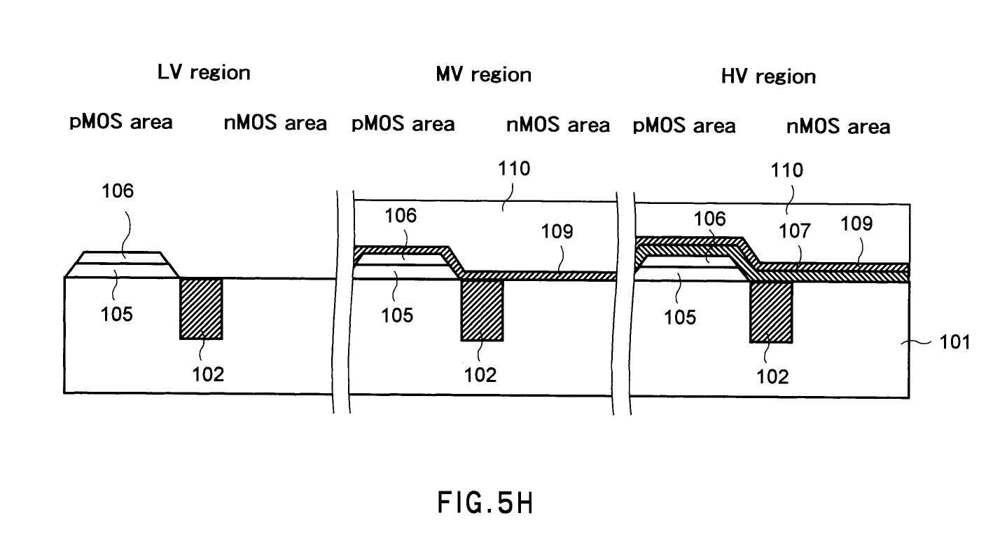

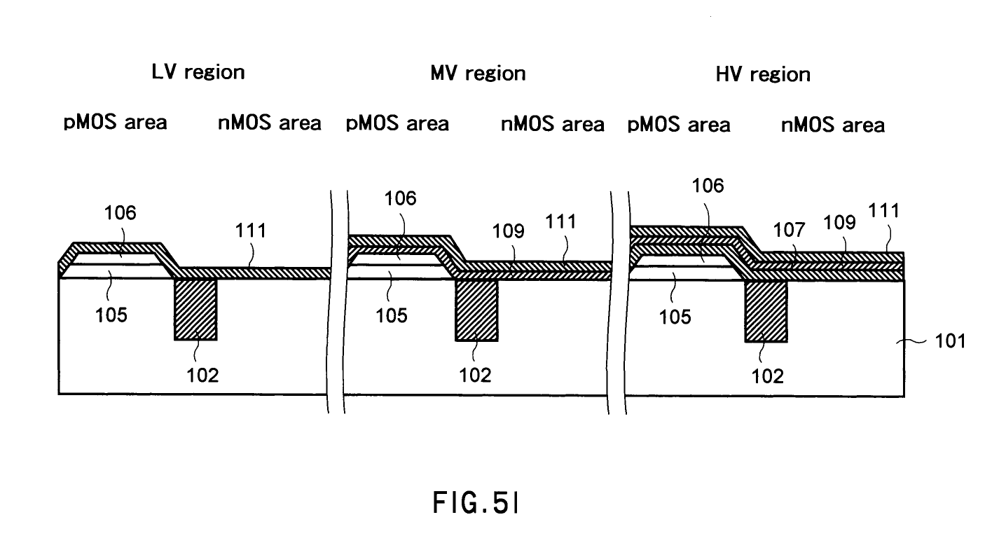

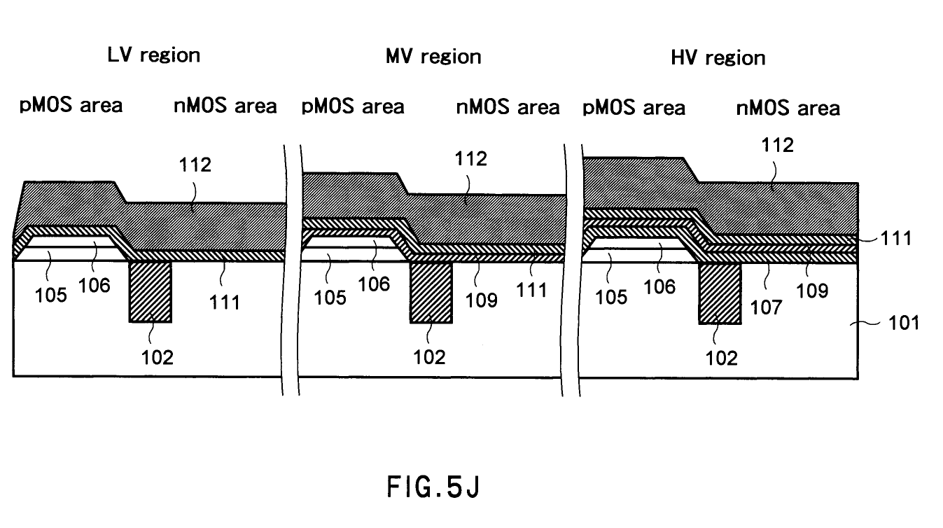

Next, before description of the embodiments according to the invention, a method of manufacturing a MOSFET according to a comparative example using a multi-oxide process will be described with reference to FIGS. 5A to 5J.

(1) As shown in FIG. 5A, STIs 102, which are insulating films for device isolation, are formed in a Si substrate 101 by a device isolation technique so as to surround active areas in which MOSFETs are to be formed.

(2) As shown in FIG. 5B, a silicon oxide film 103 is deposited on the Si substrate 101 and the STI 102 in each of the LV, MV and HV regions. The silicon oxide film 103 is made of SiO₂, and its thickness is 8 nm. Then, based on the desired characteristics of a MOSFET, a well and a channel region (not shown) are formed in each active area using a lithography technique and an ion implantation technique.

(3) As shown in FIG. 5C, after active areas in which n-type MOSFETs are to be formed (hereinafter, referred to as “NMOS areas”) in the LV, MV and HV regions are covered with resists 104, the silicon oxide films 103 in active areas in which p-type MOSFETs are to be formed (hereinafter, referred to as “PMOS areas”) in the LV, MV and HV regions are removed by wet etching. Then, the resists 104 are removed.

(4) Next, a cleaning process is performed so as to remove an about 1-nm-thick natural oxide film naturally formed on the surface of the Si substrate 101 in each PMOS area. Then, as shown in FIG. 5D, a SiGe film 105 and a silicon film 106 for protecting this SiGe film 105 are successively formed in each PMOS area of the LV, MV and HV regions by selective epitaxial growth. This selective epitaxial growth is performed by using as masks the silicon oxide films 103 in the NMOS areas. Note that the Ge concentration of the SiGe film 105 is 30% (Si_{0.7}Ge_{0.3}). The film thickness of the SiGe film 105 is 7 nm, and the film thickness of the silicon film 106 is 4 nm. Then, the silicon oxide films 103 in the NMOS areas of the LV, MV and HV regions are removed by wet etching. This exposes the laminated SiGe film 105 and silicon film 106 in each PMOS area, and exposes the surface of the Si substrate 101 in each NMOS area.

(5) As shown in FIG. 5E, a first gate insulating film 107 (SiO₂) is formed in each of the LV, MV and HV regions by thermal oxidation. The thickness of the first gate insulating film 107 is 4 nm.

By this process of forming the first gate insulating film 107, about 2 nm silicon of the silicon film 106 in each of the LV, MV and HV regions is consumed to be a silicon oxide film.

(6) As shown in FIG. 5F, with the LV and HV regions covered with resists 108, the first gate insulating film 107 in the MV region is removed by wet etching. Then, the resists 108 are removed.

(7) As shown in FIG. 5G, a second gate insulating film 109 (SiO₂) is formed in each of the LV, MV and HV regions by thermal oxidation. The thickness of the second gate insulating film 109 is 2.4 nm.

By this process of forming the second gate insulating film 109, the silicon film 106 is further consumed. Looking at the consumption by region, of the silicon film 106 in the MV region, about 1 nm silicon is consumed. Of the silicon film 106 in each of the LV and HV regions, about 0.5 nm silicon is consumed.

(8) As shown in FIG. 5H, with the MV and HV regions covered with resists 110, the first gate insulating film 107 and the second gate insulating film 109 in the LV region are removed by wet etching. Then, the resists 110 are removed.

(9) As shown in FIG. 5I, a third gate insulating film 111 is formed in each of the LV, MV and HV regions. HfSiON having a high dielectric constant is used as this third gate insulating film 111. By this process of forming the third gate insulating film 111, the silicon film 106 in each region is further consumed. The decreased thickness by the consumption differs for every region.

(10) As shown in FIG. 53, a metal layer 112 is formed in each of the LV, MV and HV regions. Used as this metal layer 112 is, for example, TaC.

For the following processes, although the detailed description is not given, gates and source/drain regions and the like are formed to form p-type MOSFETs in the PMOS areas and n-type MOSFETs in the NMOS areas, by a conventional method.

As described above, in the comparative example, the silicon film 106 for protecting the SiGe film 105 is designed to have a sufficient thickness so as to prevent all the silicon of the silicon film 106 from being oxidized during formation of the gate insulating films. After the SiGe film and the silicon film are successively formed in each of the LV, MV and HV regions, the gate insulating film having a thickness that differs for every region is formed. With this manufacturing method according to the comparative example, the SiGe film 105 can be prevented from oxidation.

Regarding the LV region, however, part of the silicon film 106 is oxidized when the first gate insulating film 107 and the second gate insulating film 109 for the MV and HV regions are formed. Also, when the first gate insulating film 107 and the second gate insulating film 109 are removed by wet etching, part of the silicon film 106 is sometimes cut. Therefore, with the method according to the comparative example, it is difficult to control the film thickness of the remaining silicon film immediately before forming the third gate insulating film 111. That is, there is a problem that controllability of the film thickness of the silicon film 106 is low.

This results in variations in a threshold voltage even among MOSFETs formed in the same region (the LV, MV or HV region).

To make the gate insulating film thinner, it is preferable that the film thickness of the silicon film 106 be as thin as possible. With the method according to the comparative example, however, because controllability of the film thickness of the silicon film is low, the formed silicon film 106 needs to be made thicker than usual. Therefore, a silicon film that is not oxidized upon formation of a gate insulating film is left. This remaining silicon film 106 without being oxidized becomes a channel of a MOSFET. As a result, controllability of the threshold voltage by the SiGe film decreases.

The invention is made based on the above original technical understanding. As will be described in each embodiment below, the invention focuses on the LV region in which the MOSFET whose threshold voltage needs to be controlled at the highest accuracy is formed, and solves a problem of low controllability of the film thickness of a protective film for a SiGe film, such as the above silicon film.

Hereinbelow, first to fourth embodiments according to the invention will be described with reference to the drawings. Note that elements having equivalent functions are denoted by the same reference numerals, and the detailed descriptions thereof will not be given.

In the first and second embodiments, a SiGe film is formed in each of the LV, MV and HV regions. After a gate insulating film is formed in the MV and HV regions, a silicon film is formed on the SiGe film in the LV region.

In the third and fourth embodiments, a SiGe film is formed only in the LV region, and the SiGe film and a silicon film are successively formed.

### First Embodiment

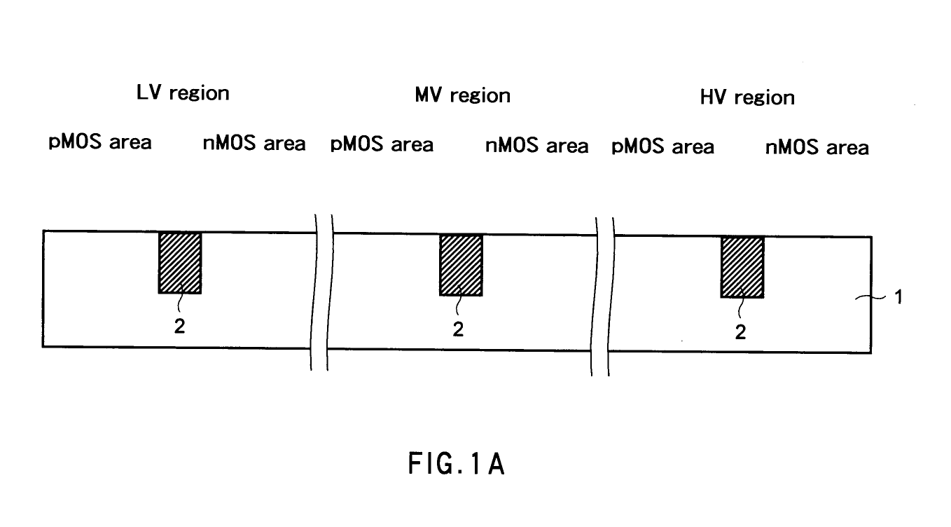

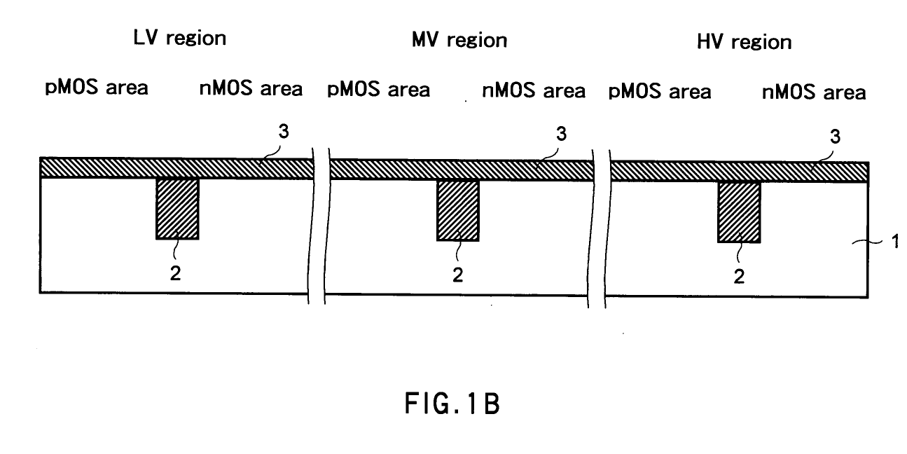

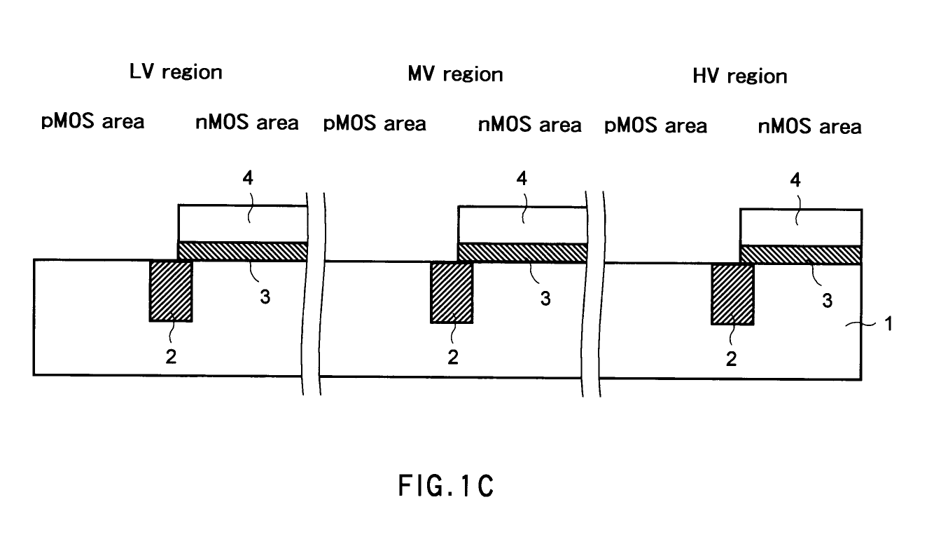

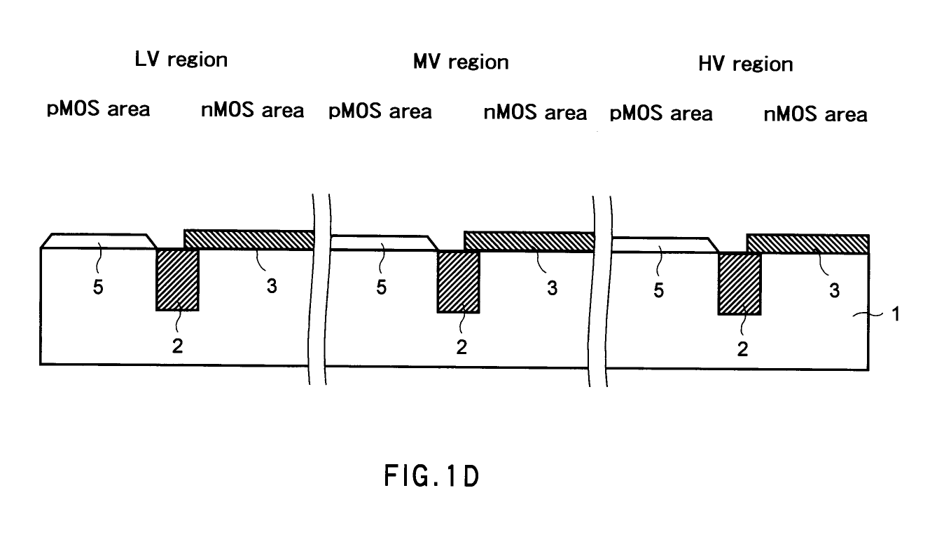

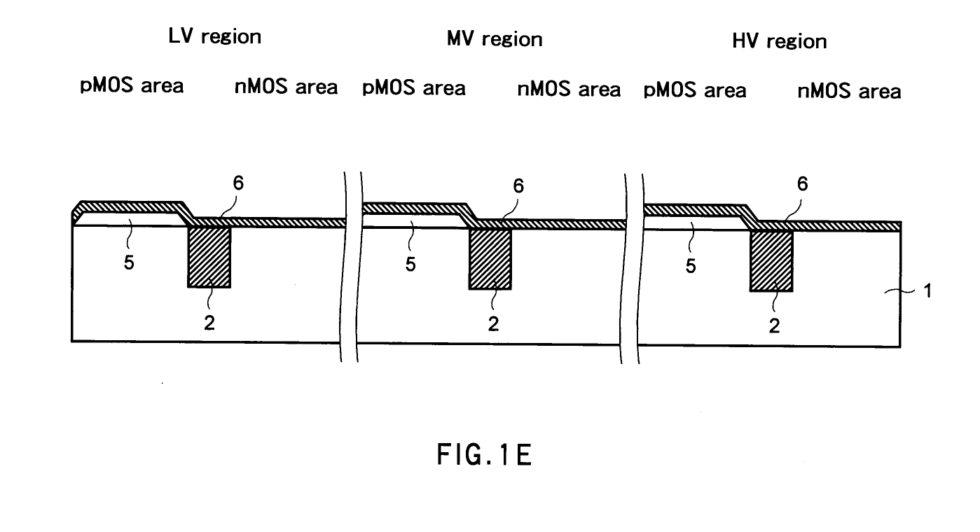

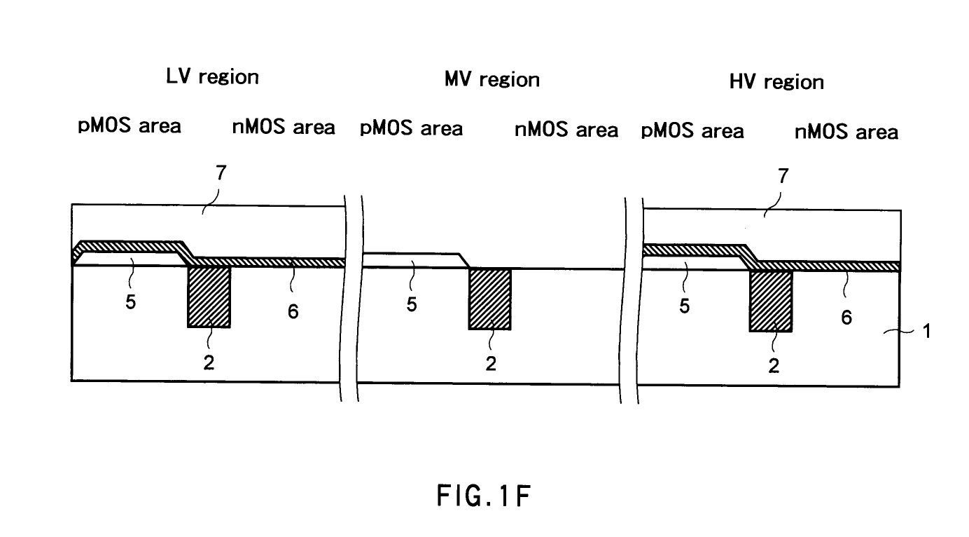

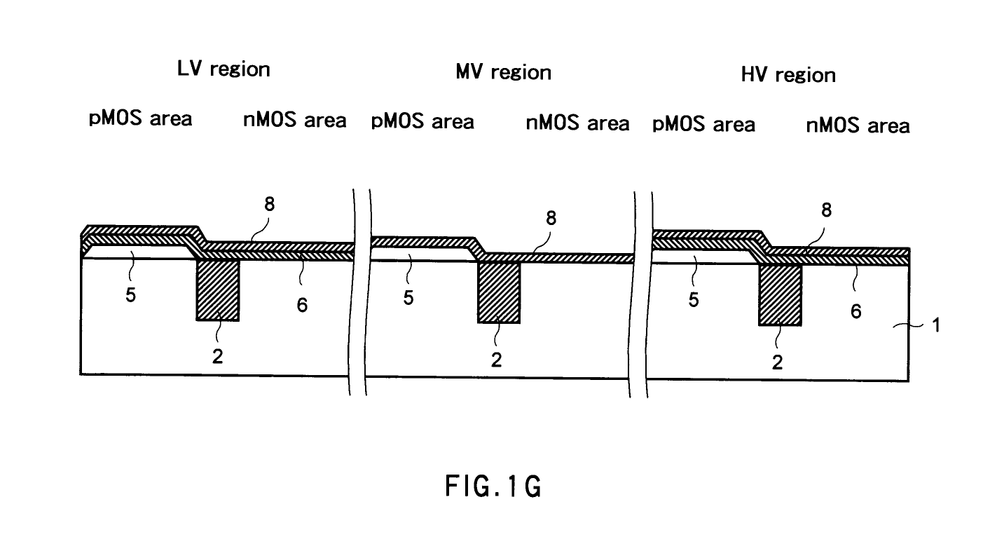

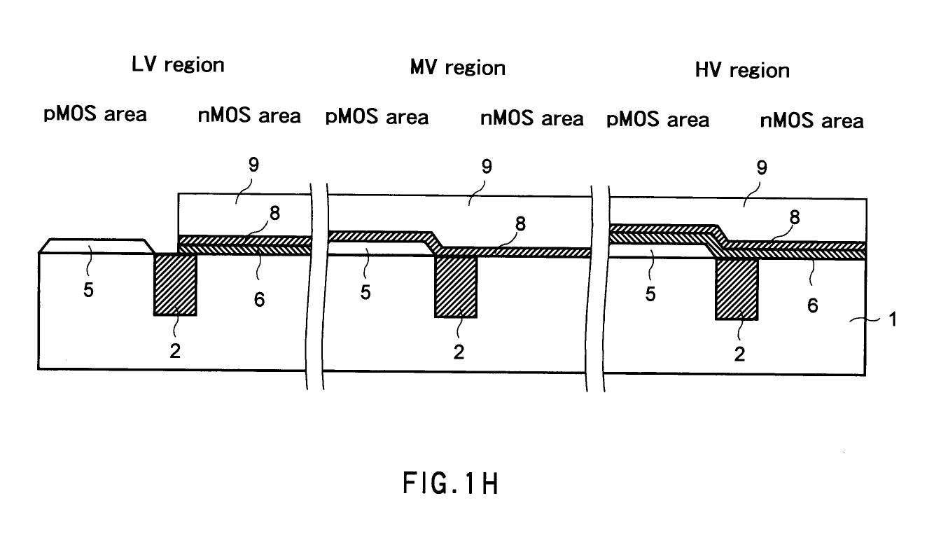

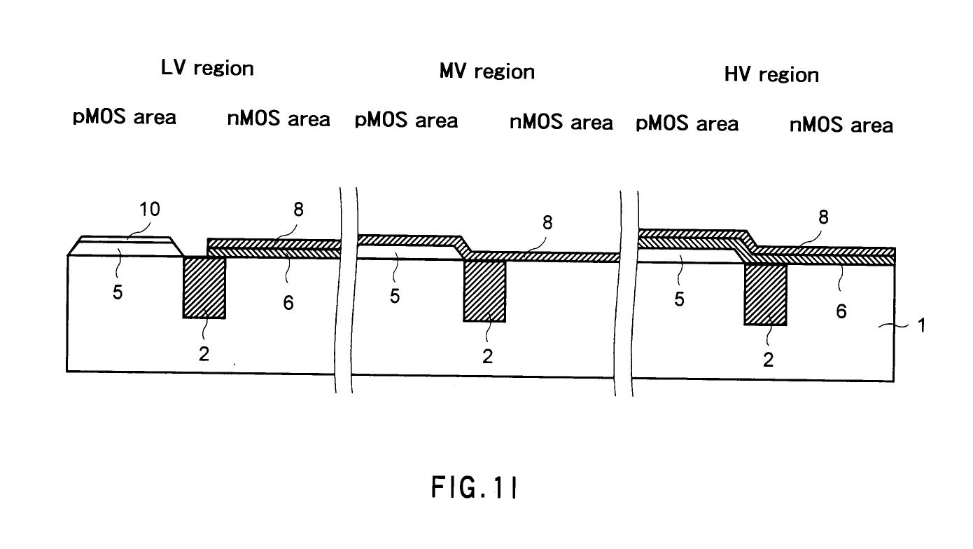

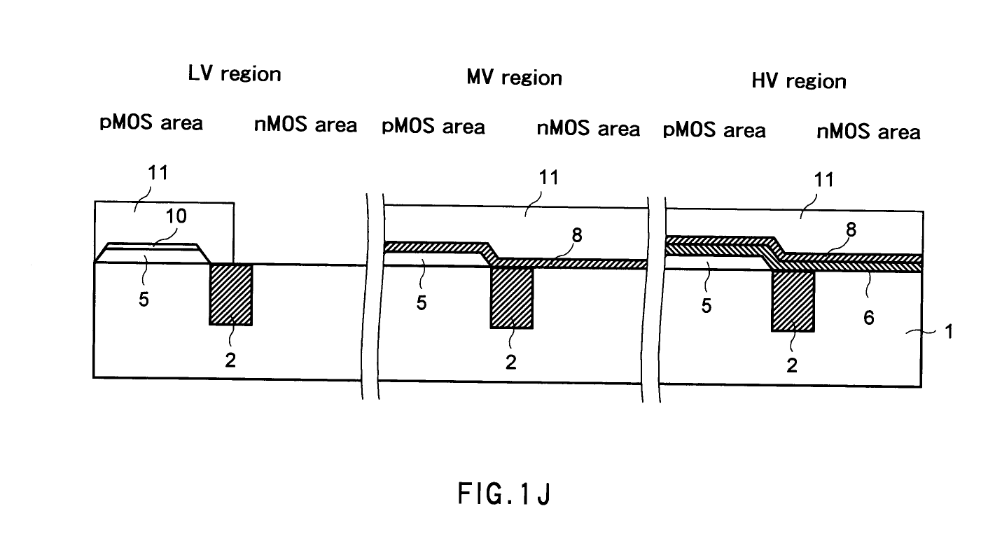

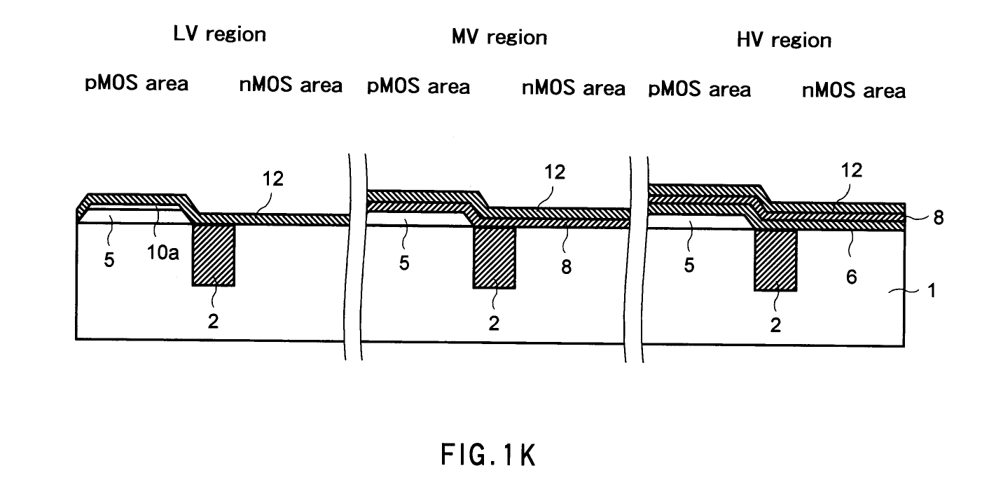

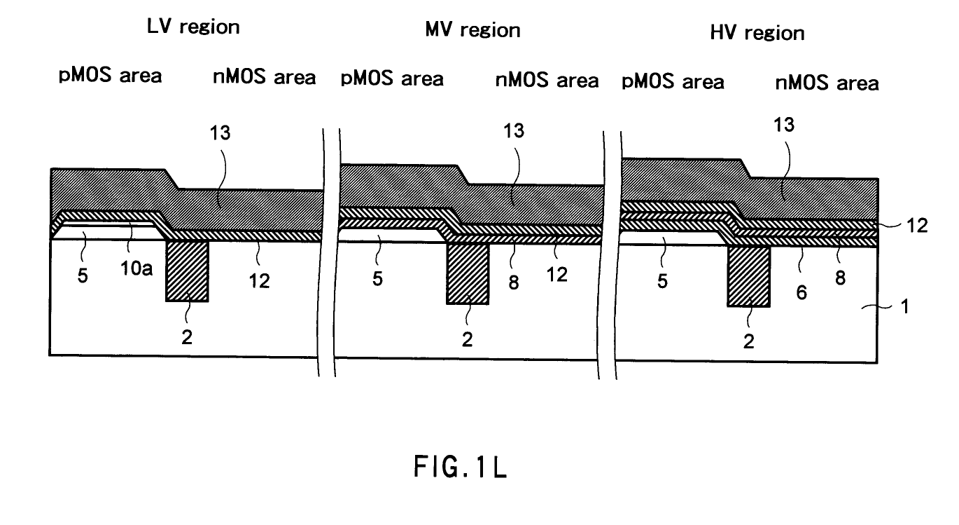

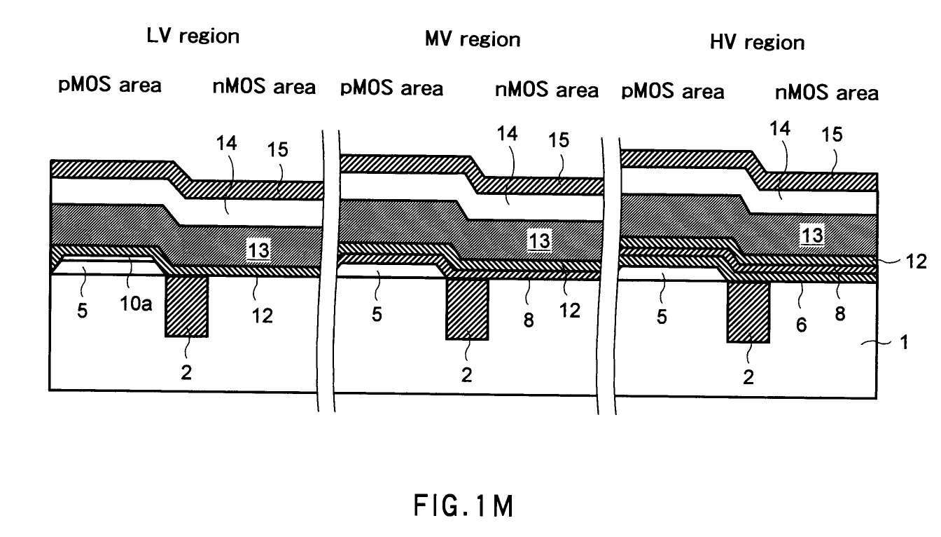

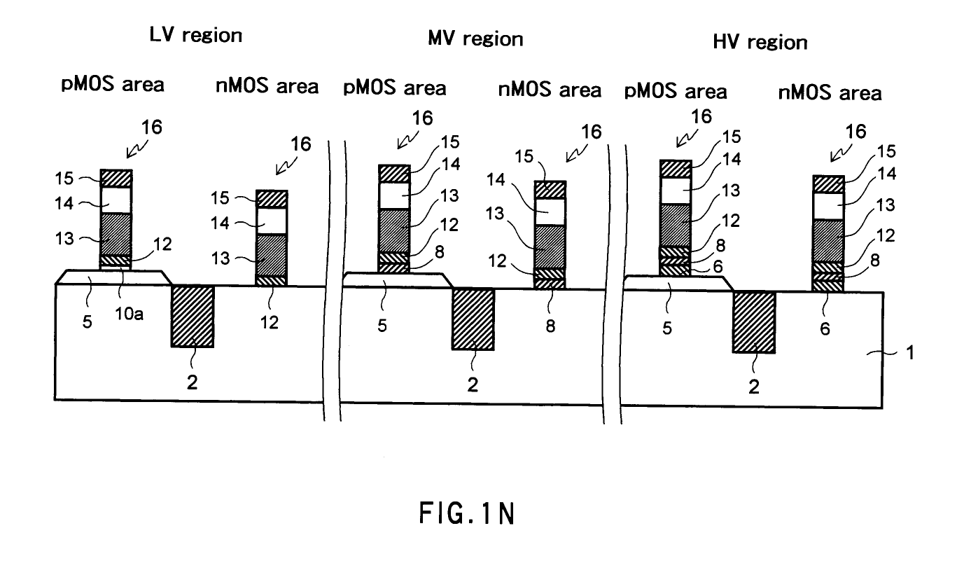

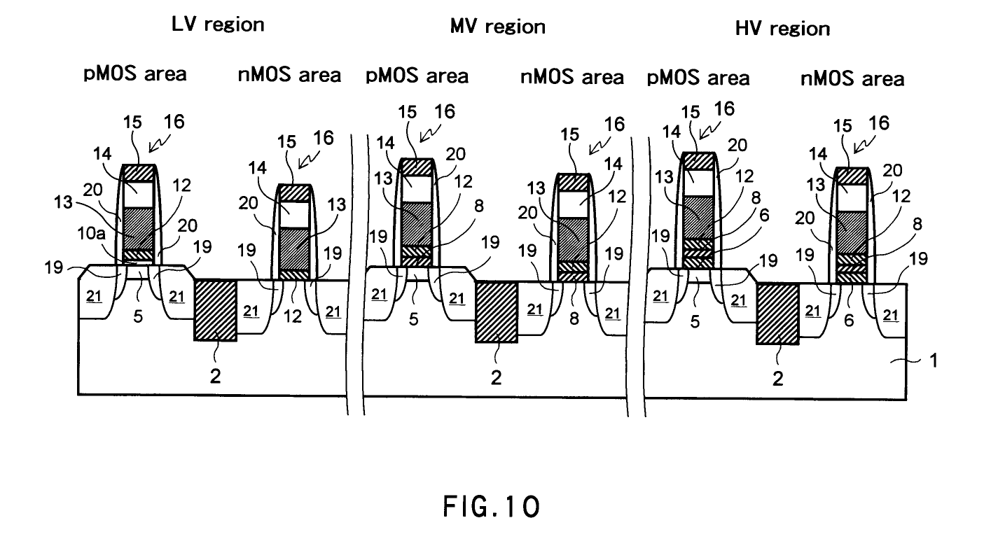

With reference to FIGS. 1A to 1O, a method of manufacturing a semiconductor device according to the first embodiment is now described.

(1) As shown in FIG. 1A, STIs 2, which are insulating films for device isolation, are formed in a Si substrate 1.

(2) As shown in FIG. 1B, a silicon oxide film 3 is deposited on the Si substrate 1 and the STI 2 in each of the LV, MV and HV regions. The silicon oxide film 3 is made of SiO₂, and its thickness is, for example, 8 nm. Then, a well and a channel region (not shown) are formed by ion implantation.

(3) As shown in FIG. 1C, with each NMOS area in the LV, MV and HV regions covered with a resist 4, the silicon oxide film 3 in each PMOS area in the LV, MV and HV regions is removed by wet etching. Then, the resist 4 is removed.

(4) As shown in FIG. 1D, after a cleaning process is performed so as to remove a natural oxide film naturally formed on the surface of the Si substrate 1 in the PMOS area, a SiGe film 5 is formed in each PMOS area of the LV, MV and HV regions by selective epitaxial growth. This selective epitaxial growth is performed by using as a mask the silicon oxide film 3 in the NMOS area. The Ge concentration of the SiGe film 5 is, for example, 30% (Si_{0.7}Ge_{0.3}). Note that the film thickness of the SiGe film 5 is, for example, 7 nm. Then, the silicon oxide films 3 in the NMOS areas of the LV, MV and HV regions are removed by wet etching.

(5) As shown in FIG. 1E, a first gate insulating film 6 is formed in each of the LV, MV and HV regions. This first gate insulating film 6 is, for example, SiO₂ formed by thermal oxidation, and its thickness is 4 nm. The first gate insulating film 6 is to be a part of the gate insulating film of MOSFET in the HV region.

(6) As shown in FIG. 1F, with the LV and HV regions covered with resists 7, the first gate insulating film 6 in the MV region is removed by wet etching.

(7) As shown in FIG. 1G, after the resists 7 covering the LV and HV regions are removed, a second gate insulating film 8 is formed in each of the LV, MV and HV regions. This second gate insulating film 8 is, for example, SiO₂ formed by thermal oxidation, and its thickness is 2.4 nm. The second gate insulating film 8 is to be a part of the gate insulating film of MOSFET in the MV and HV regions.

(8) As shown in FIG. 1H, after the NMOS area of the LV region, and the MV and HV regions are covered with resists 9, the first gate insulating film 6 and the second gate insulating film 8 in the PMOS area of the LV region are removed by wet etching. Then, the resists 9 are removed.

(9) As shown in FIG. 1I, after a cleaning process is performed so as to remove a natural oxide film naturally formed on the SiGe film 5 in the PMOS area of the LV region, a silicon film 10 is formed on the SiGe film 5 by selective epitaxial growth. Note that, to reduce the thickness of the whole gate insulating film, it is preferable that this silicon film 10 have such a thickness, for example, 1 nm, that all the silicon film 10 is oxidized when a third gate insulating film 12 to be described later is formed.

(10) As shown in FIG. 1J, with the PMOS area of the LV region, and the MV and HV regions covered with resists 11, the first gate insulating film 6 and the second gate insulating film 8 in the NMOS area of the LV region is removed by wet etching.

(11) As shown in FIG. 1K, after the resists 11 are removed, the third gate insulating film 12 is formed in each of the LV, MV and HV regions. Used as the third gate insulating film 12 is a high-k film (for example, HfSiON). The film thickness of the third gate insulating film 12 is, for example, 3 nm. The third gate insulating films 12 are to be gate insulating films of MOSFETs in the LV, MV and HV regions. Note that when the third gate insulating film 12 is formed, at least part of the silicon film 10 is oxidized to be a silicon oxide film 10a (SiO₂). Preferably, by the forming of the third gate insulating film 12, just all the silicon film 10 is oxidized to be the silicon oxide film 10a.

(12) As shown in FIG. 1L, a metal layer 13 is formed on the third gate insulating film 12 in each of the LV, MV and HV regions. Used as this metal layer 13 is, for example, TaC.

Then, gates and source/drain regions and the like are formed to fabricate MOSFETs. An example of its method is described below.

(13) As shown in FIG. 1M, a polysilicon film 14 and a silicon oxide film 15 (SiO₂) are sequentially formed on the metal layer 13 in each of the LV, MV and HV regions.

(14) Next, a resist pattern (not shown) is formed in accordance with a desired gate electrode shape on the silicon oxide film 15 of each of the LV, MV and HV regions.

(15) As shown in FIG. 1N, by using this resist pattern as a mask, the silicon oxide film 15, the polysilicon film 14, the metal layer 13, the third gate insulating film 12 and the silicon oxide film 10a are etched by reactive ion etching (RIE). Thus, gate structures 16 are formed in each of the LV, MV and HV regions.

(16) As shown in FIG. 10, a dopant is ion-implanted into source/drain extension regions 19. Sidewall insulating films 20 are formed on sidewalls of the gate structures 16 using a sidewall processing technique. The dopant is ion-implanted into source/drain regions 21.

(17) Next, using a silicide technique, the surfaces of the silicon oxide films 15 and the source/drain regions 21 are converted into silicide.

By the processes described above, p-type MOSFETs in the PMOS areas and n-type MOSFETs in the NMOS areas are formed.

Hereinbefore, in a manufacturing method according to the present embodiment, first, the SiGe film 5 is formed on the PMOS area in each of the LV, MV and HV regions. After the gate insulating films (the first gate insulating film 8 and the second gate insulating film 12) in the MV and HV regions are formed, the silicon film 10 is formed on the SiGe film 5 in the LV region.

This method eliminates consumption of the silicon film 10. The consumption is caused by oxidization or etching of the silicon film 10 by the process related to other regions (MV, HV), as in the aforementioned comparative example. Therefore, according to the present embodiment, controllability of the film thickness of the silicon film 10 improves. For example, if the thickness of the silicon film 10 is set to such a thickness as to be consumed by formation of the third gate insulating film 12, it is possible for all the silicon film 10 to be oxidized by formation of the gate insulating film 12, so that there is no remaining silicon film 10.

Thus, it is possible to improve controllability of the threshold voltage of the p-type MOSFET in the LV region.

Note that the first gate insulating film 6 and the second gate insulating film 8 are formed by thermal oxidation in the above description, but the formation is not limited to this. They may be formed using chemical vapor deposition (CVD) or atomic layer deposition (ALD) in place of thermal oxidation. In this case, when the first gate insulating film 6 and the second gate insulating film 8 are formed, the SiGe film 5 is not subjected to thermal oxidation. Therefore, controllability of the threshold voltage can be further improved.

As materials of the first gate insulating film 6 and the second gate insulating film 8, a silicon oxynitride film (SiON) may be used in place of the silicon oxide film (SiO₂).

Hereinbefore, according to the present embodiment, the interface characteristics between the SiGe film 5 and the third gate insulating film 12 of the p-type MOSFET are prevented from deteriorating in the multi-oxide process. This enables controllability of the threshold voltage of the p-type MOSFET in the LV region to be improved.

### Second Embodiment

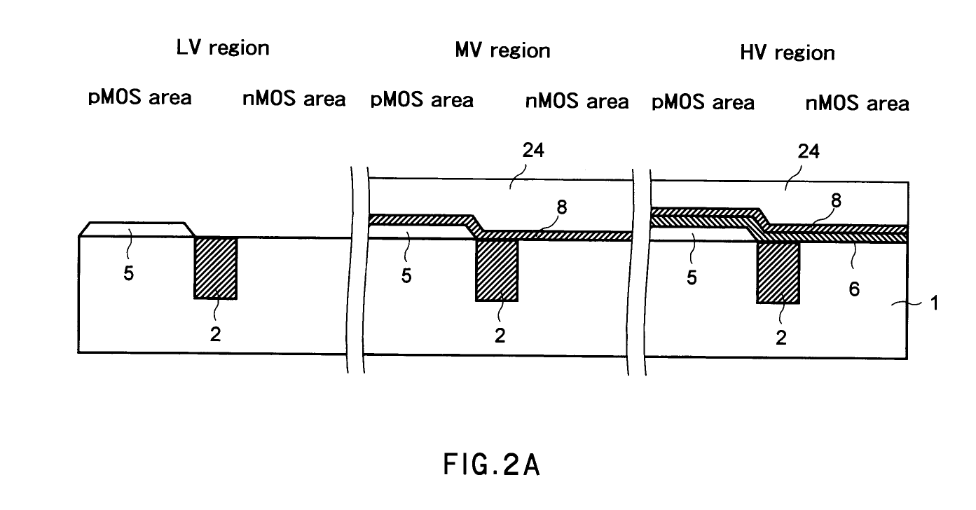

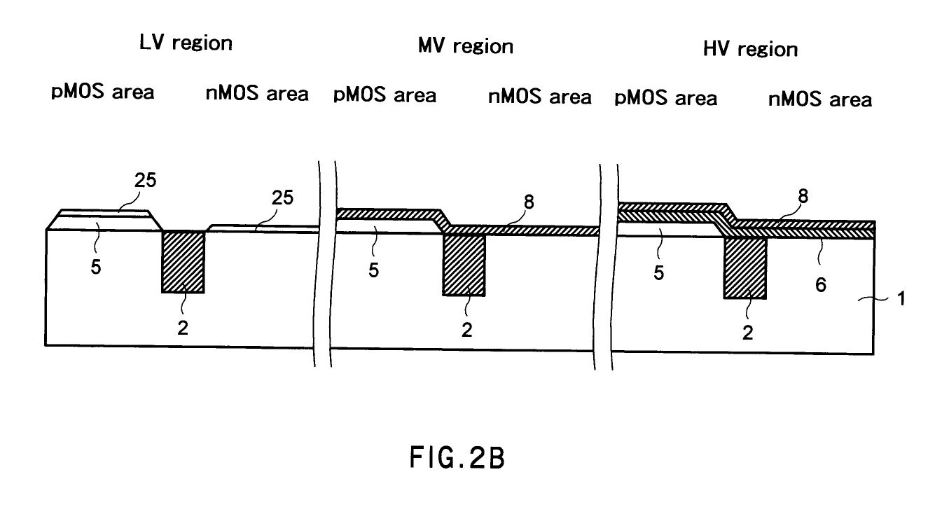

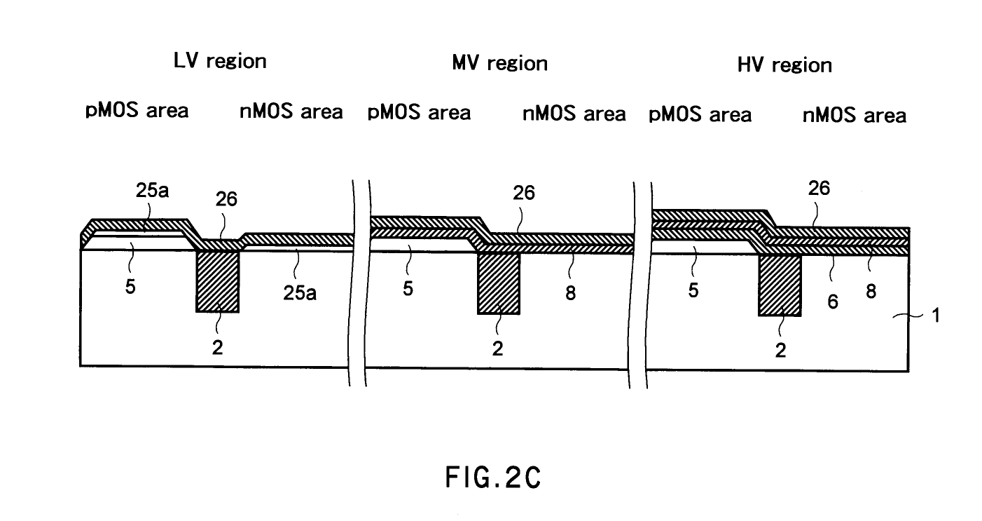

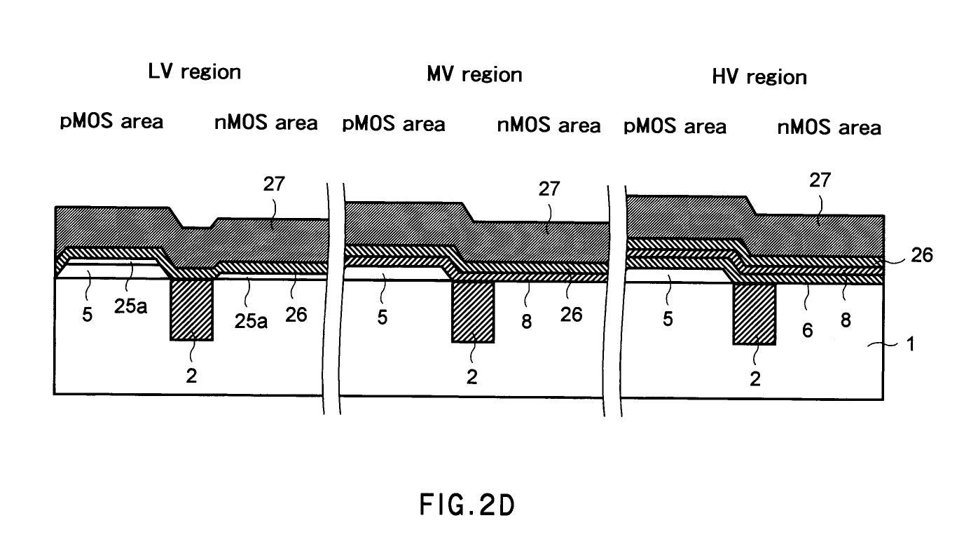

With reference to FIGS. 2A to 2D, a method of manufacturing a semiconductor device according to a second embodiment is now described. One of differences between the present embodiment and the first embodiment is that after a SiGe film is formed in the PMOS area in each of the LV, MV and HV regions and a gate insulating film is formed in each of the MV and HV regions, a silicon film is formed not only in the PMOS area but also in the NMOS area of the LV region. This can reduce the number of processes to be less than that in the first embodiment.

The processes up to the process of forming the second insulating film 8 (FIGS. 1A to 1G) described in the first embodiment are the same as in the present embodiment, and therefore the subsequent processes are described below.

(1) As shown in FIG. 2A, with the MV and HV regions covered with resists 24, the first gate insulating film 6 and the second gate insulating film 8 in the LV region are removed by wet etching. Then, the resists 24 are removed.

(2) As shown in FIG. 2B, a cleaning process is performed so as to remove a natural oxide film naturally formed on the Si substrate 1 in the LV region, and a silicon film 25 is formed in the PMOS area and the NMOS area of the LV region by selective epitaxial growth. Note that, to reduce the thickness of the whole gate insulating film, it is preferable that the film thickness of the silicon film 25 be such a thickness, for example, 1 nm, that all the silicon film 25 is oxidized when a third gate insulating film 26 to be described later is formed.

(3) As shown in FIG. 2C, the third gate insulating film 26 is formed in the LV region in each of the LV, MV and HV regions. Used as the third gate insulating film 26 is a high-k film (for example, HfSiON). The film thickness of the third gate insulating film 26 is, for example, 3 nm. Note that when the third gate insulating film 26 is formed, at least part of the silicon film 25 is oxidized to be a silicon oxide film 25a (SiO₂). Preferably, by forming the third gate insulating film 26, just all the silicon film 25 is oxidized to be the silicon oxide film 25a.

(4) As shown in FIG. 2D, a metal layer 27 is formed on the third gate insulating film 26 in each of the LV, MV and HV regions. Used as the material of this metal layer 27 is, for example, TaC.

Hereafter, through the same processes as those described in the first embodiment, gates, source/drain regions and the like are formed, thereby fabricating p-type MOSFETs in the PMOS areas and n-type MOSFETs in the NMOS areas.

As described above, in the present embodiment, unlike the first embodiment, the silicon film 25 is formed not only in the PMOS area but also in the NMOS area of the LV region. When the third gate insulating film 26 is formed, at least part of the silicon film 25 is oxidized to be a silicon oxide film. Compared to the first embodiment, it is possible to omit a process of removing the first gate insulating film 6 and the second gate insulating film 8 in the NMOS area of the LV region (see FIG. 1J). Therefore, the number of processes can be reduced to be less than that in the first embodiment.

Hereinbefore, according to the present embodiment, the same effects as in the first embodiment can be obtained, and furthermore the number of processes can be reduced.

### Third Embodiment

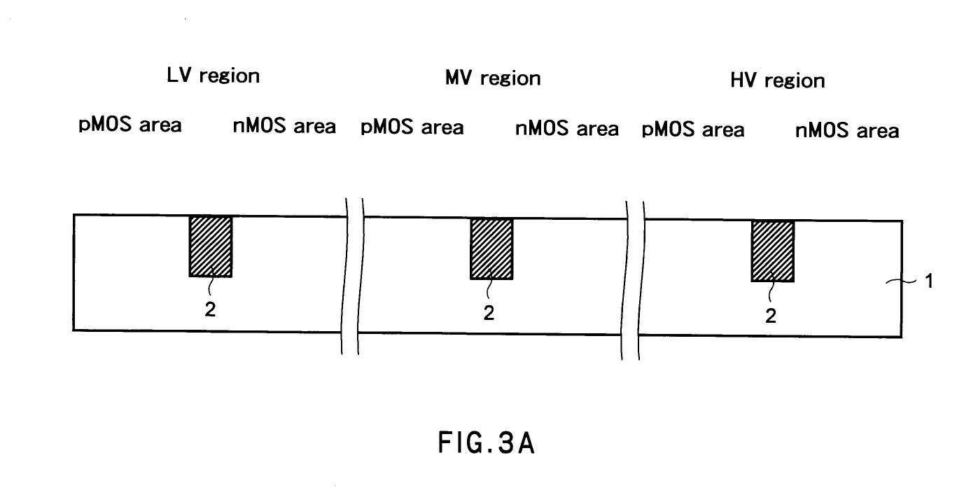

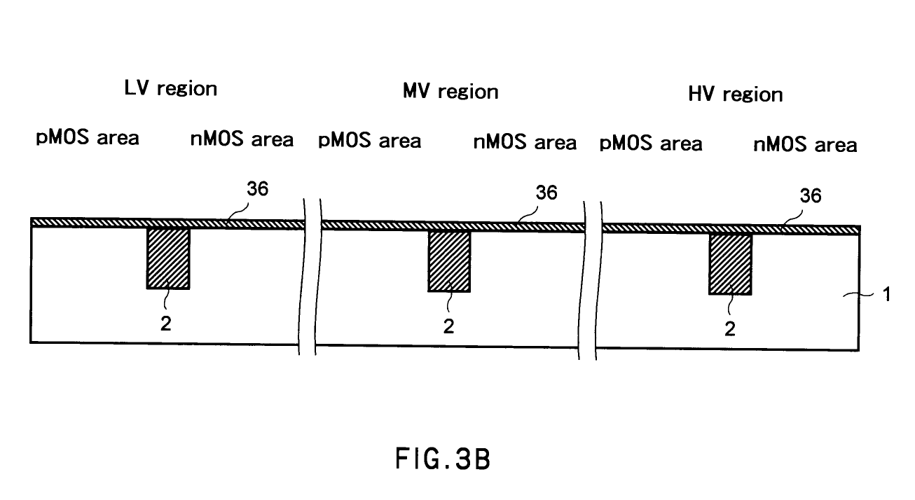

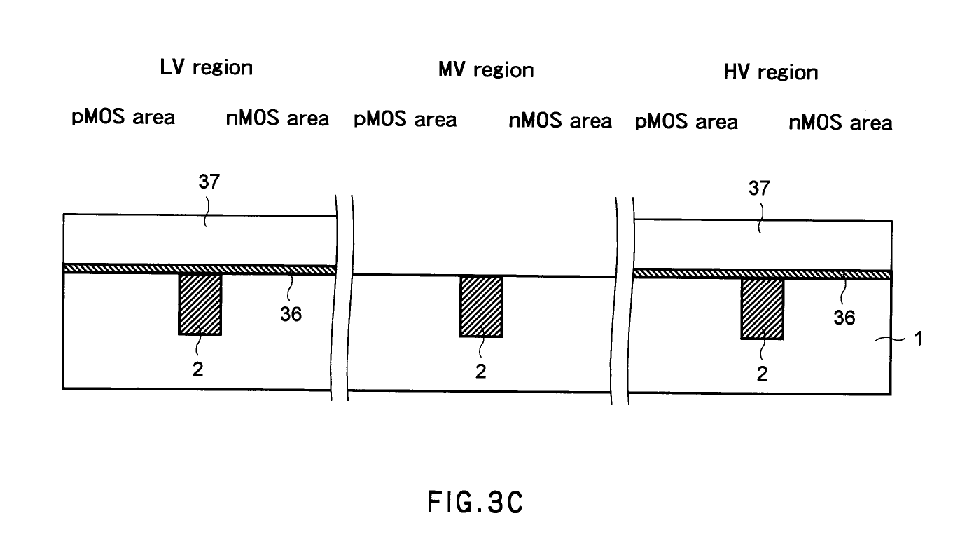

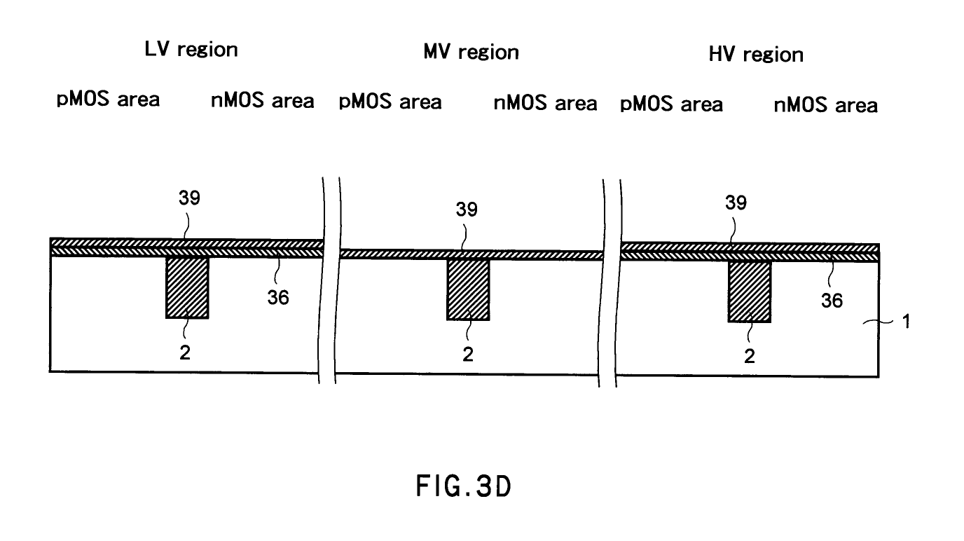

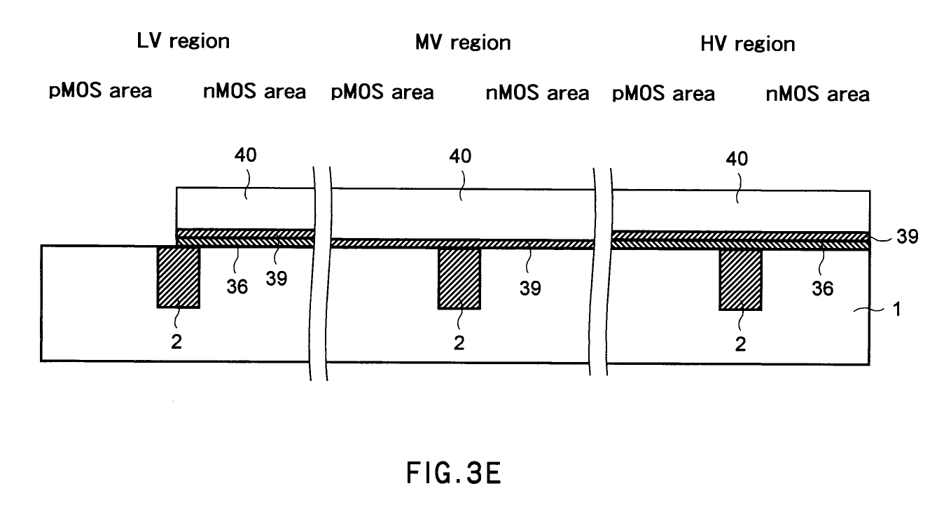

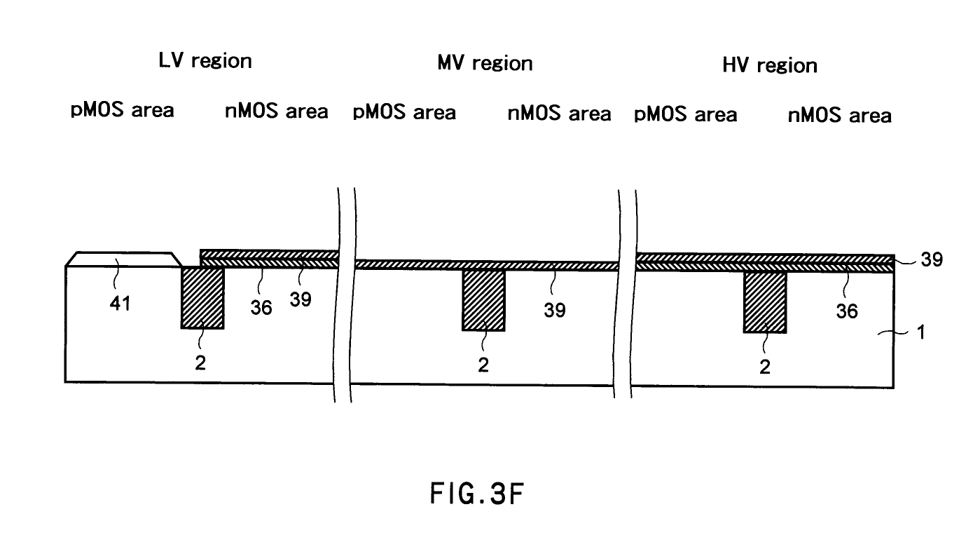

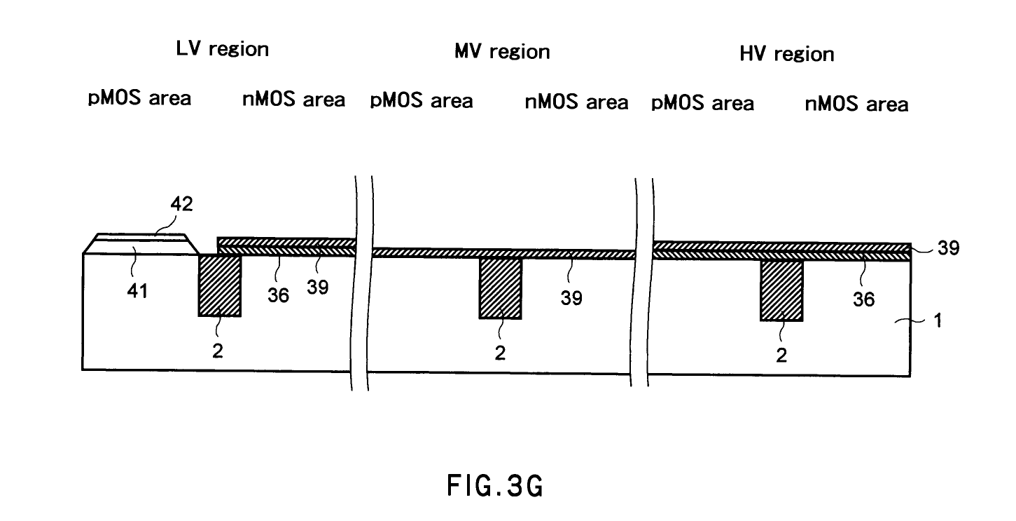

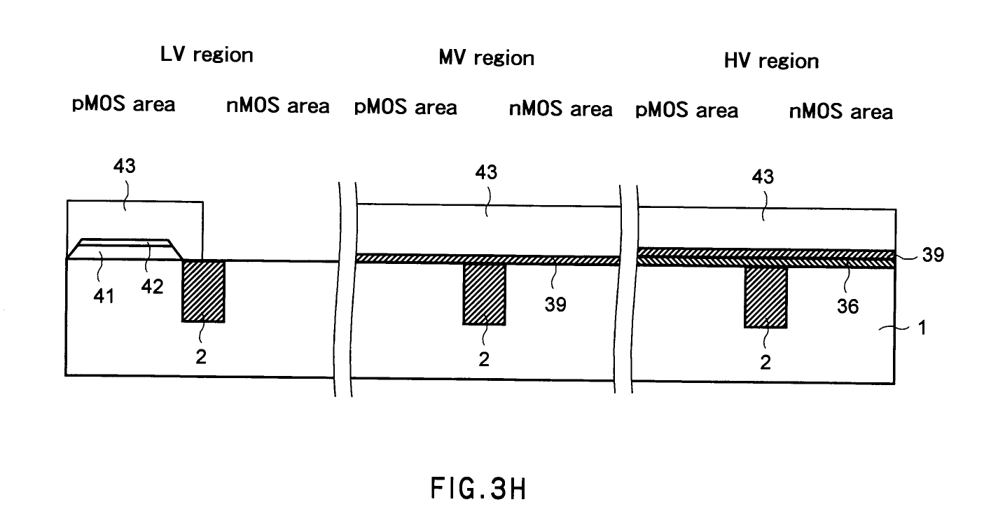

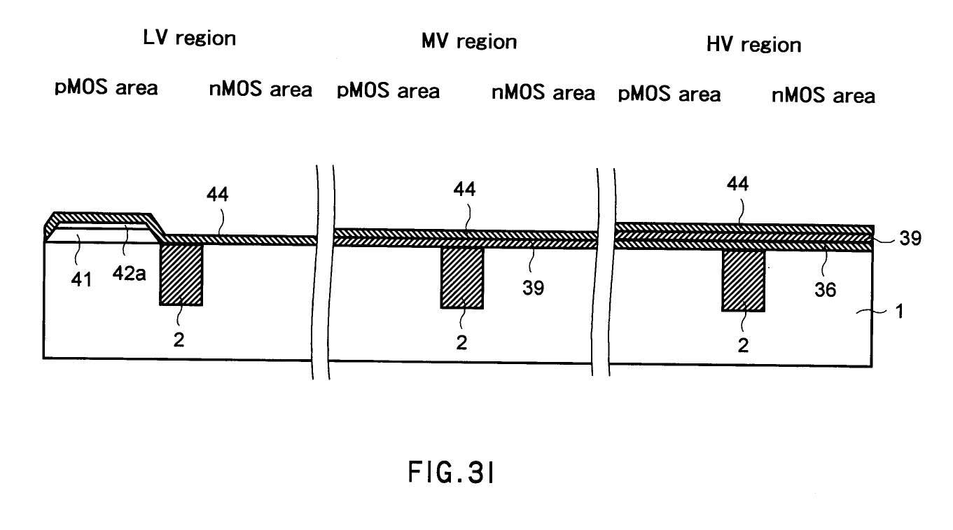

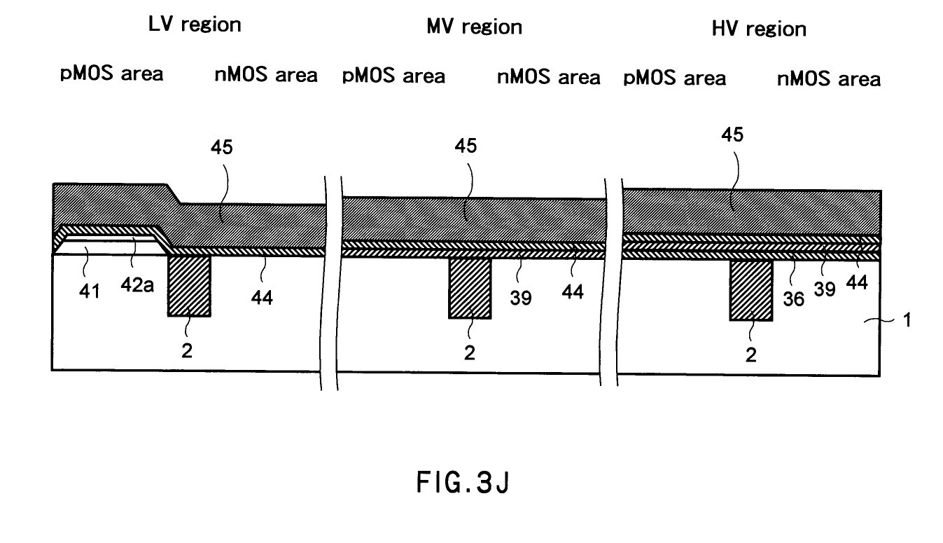

With reference to FIGS. 3A to 33, a third embodiment is now described. In the present embodiment, unlike the first and second embodiments, a SiGe film is formed only in the LV region, as described above. One of differences of the present embodiment from the first and second embodiments is that after a gate insulating film is formed in each of the MV and HV regions, a SiGe film and a silicon film are successively formed in the PMOS area of the LV region. This can avoid exposing the SiGe film to oxidization and etching by processes from forming of the SiGe film to forming of the silicon film. The controllability of the threshold voltage can further be improved.

The processes up to the process of forming the silicon oxide film 3, the well and the channel (FIGS. 1A to 1B) described in the first embodiment are the same as those in the present embodiment, and therefore the subsequent processes are described below.

(1) As shown in FIG. 3A, the silicon oxide film 3 is removed by wet etching.

(2) As shown in FIG. 3B, a first gate insulating film 36 is formed in each of the LV, MV and HV regions. This first gate insulating film 36 is, for example, SiO₂ formed by thermal oxidation, and its thickness is 4 nm.

(3) As shown in FIG. 3C, after the LV and HV regions are covered with resists 37, the first gate insulating film 36 in the MV region is removed by wet etching. Then, the resists 37 are removed.

(4) As shown in FIG. 3D, the second gate insulating film 39 is formed in each of the LV, MV and HV regions. This second gate insulating film 39 is, for example, SiO₂ formed by thermal oxidation, and its thickness is 2.4 nm.

(5) As shown in FIG. 3E, after the MV region, the HV region and the NMOS area of the LV region are covered with resists 40, the first gate insulating film 36 and the second gate insulating film 39 in the PMOS area of the LV region are removed by wet etching. Then, the resists 40 are removed.

(6) As shown in FIG. 3F, after a cleaning process is performed so as to remove a natural oxide film naturally formed in the PMOS area of the LV region, a SiGe film 41 is formed in the PMOS area of the LV region by selective epitaxial growth. The Ge concentration of the SiGe film 41 is, for example, 30% (Si_{0.7}Ge_{0.3}). Note that the film thickness of the SiGe film 41 is, for example, 7 nm.

(7) As shown in FIG. 3G, a silicon film 42 is formed on the SiGe film 41 by selective epitaxial growth. Note that, to reduce the thickness of the whole gate insulating film, it is preferable that the film thickness of the silicon film 42 be such a thickness, for example, 1 nm, that all the silicon film 42 is oxidized when a third gate insulating film 44 to be described later is formed.

(8) As shown in FIG. 3H, after the MV region, the HV region and the PMOS area of the LV region are covered with resists 43, the first gate insulating film 36 and the second gate insulating film 39 in the NMOS area of the LV region are removed by wet etching. Then, the resists 43 are removed.

(9) As shown in FIG. 3I, third gate insulating films 44 are formed. Used as the third gate insulating film 44 is a high-k film (for example, HfSiON). The film thickness of the third gate insulating film 44 is, for example, 3 nm. Note that when the third gate insulating film 44 is formed, at least part of the silicon film 42 is oxidized to be a silicon oxide film 42a (SiO₂). Preferably, by forming the third gate insulating film 44, just all the silicon film 42 is oxidized to be the silicon oxide film 42a.

(10) As shown in FIG. 33, a metal layer 45 is formed on the third gate insulating film 44 in each of the LV, MV and HV regions. Used as the material of this metal layer 45 is, for example, TaC.

Hereafter, through the same processes as those described in the first embodiment, gates, source/drain regions and the like are formed, thereby fabricating p-type MOSFETs in the PMOS areas and n-type MOSFETs in the NMOS areas.

Note that as the materials of, the first gate insulating film 36 and the second gate insulating film 39, a silicon oxynitride film (SiON) may be used in place of the silicon oxide film (SiO₂).

As described above, in the present embodiment, the first gate insulating film 36 and the second gate insulating film 39, which function as gate insulating films in the MV and HV regions, are formed, and then the SiGe film 41 is formed in the PMOS area of the LV region. Subsequent to this, the silicon film 42 is formed.

Thus, it is possible to avoid oxidization of the SiGe film 41 by the process of forming a gate insulating film in the MV/HV region, and cutting of the SiGe film 41 by wet etching during removal of a gate insulating film. This further improves the quality of the interface between the SiGe film and the gate insulating film in the LV region.

Hereinbefore, according to the present embodiment, the controllability of the threshold voltage of the p-type MOSFET in the LV region can further be improved compared to the first and second embodiments.

### Fourth Embodiment

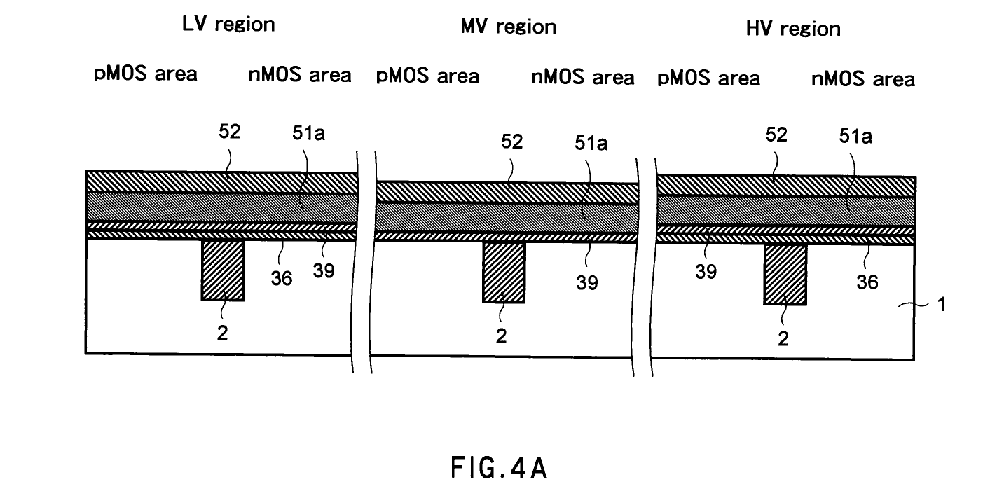

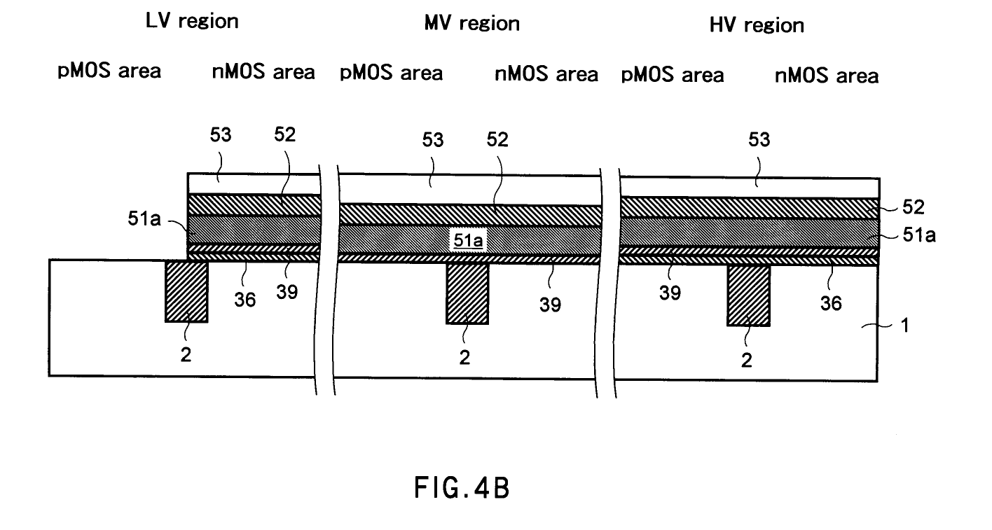

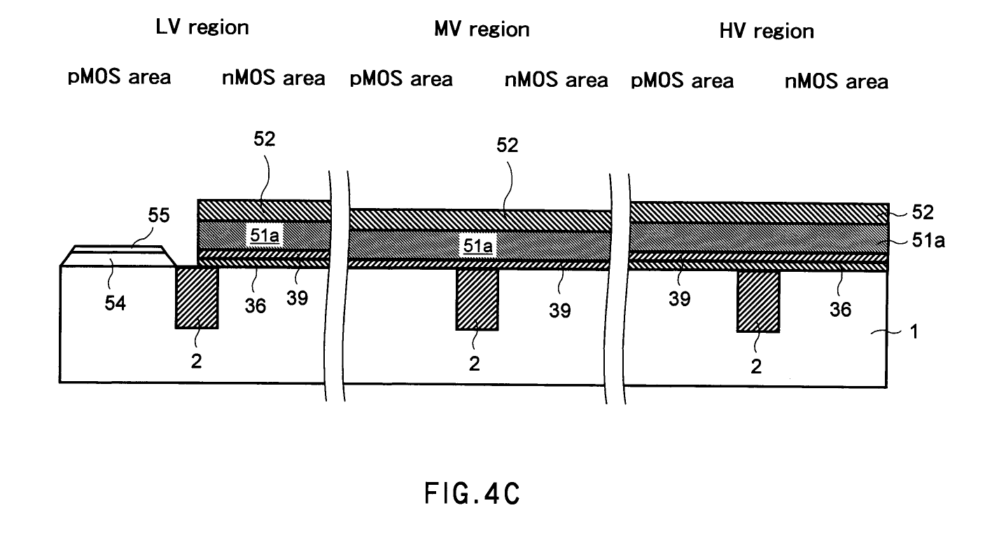

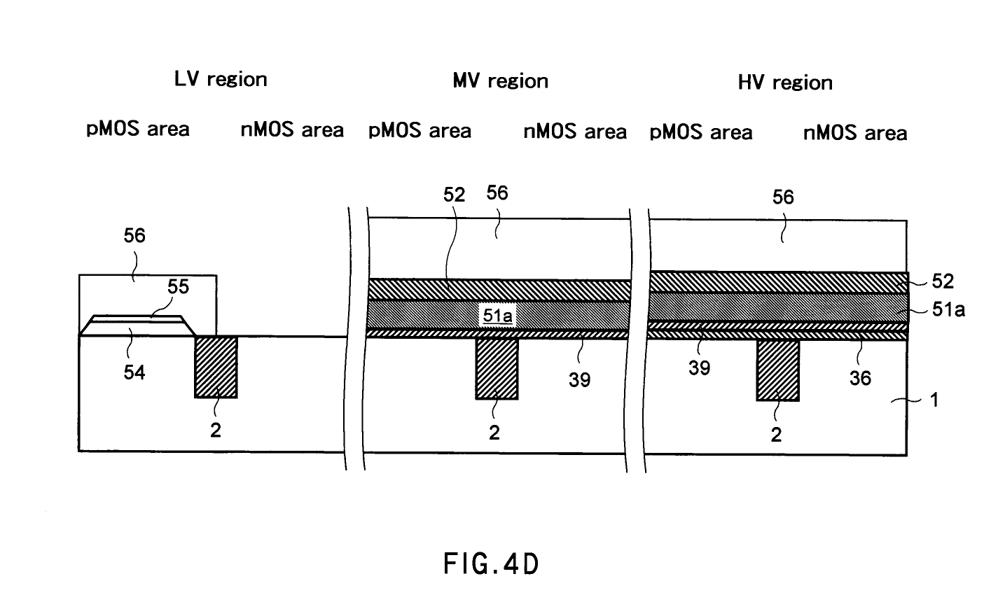

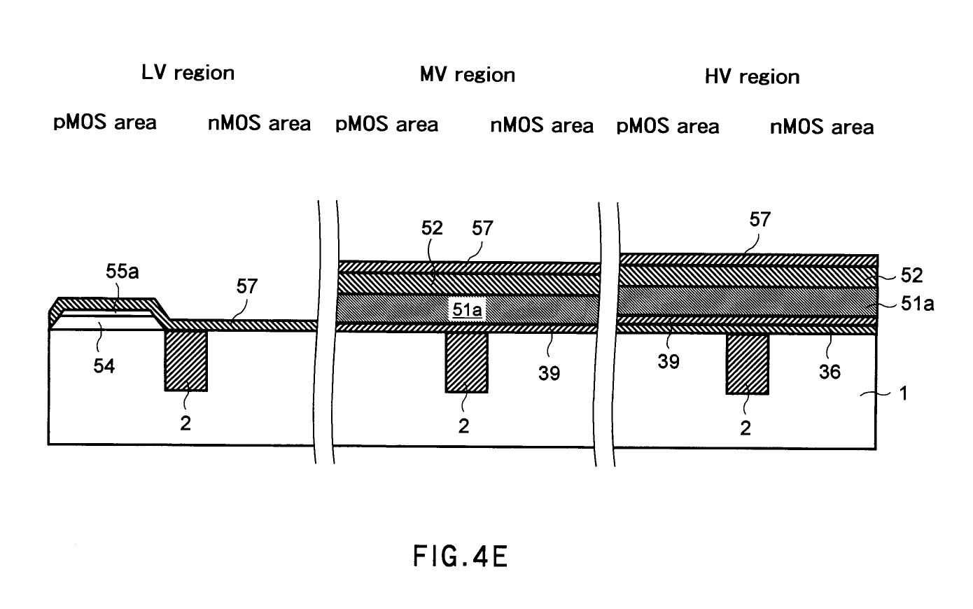

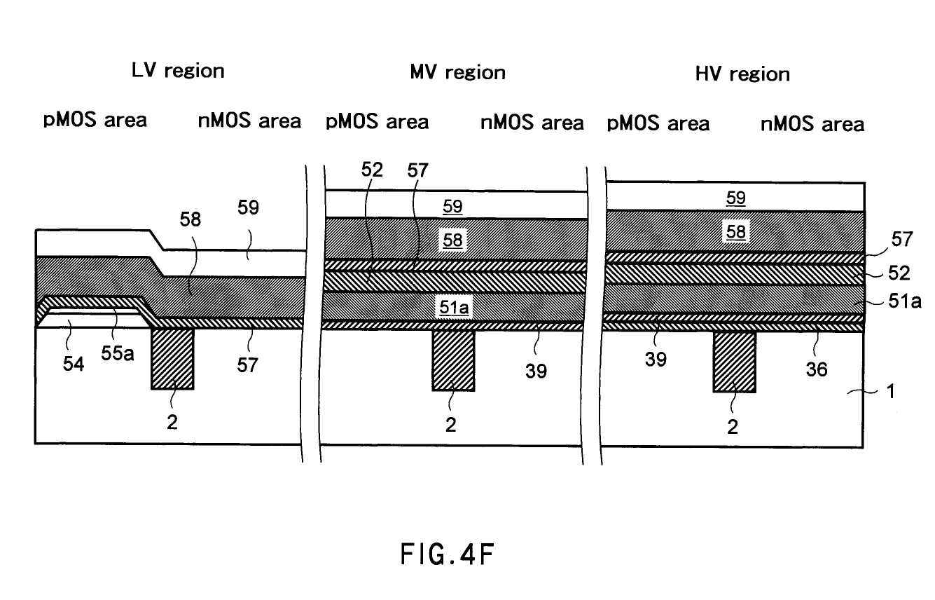

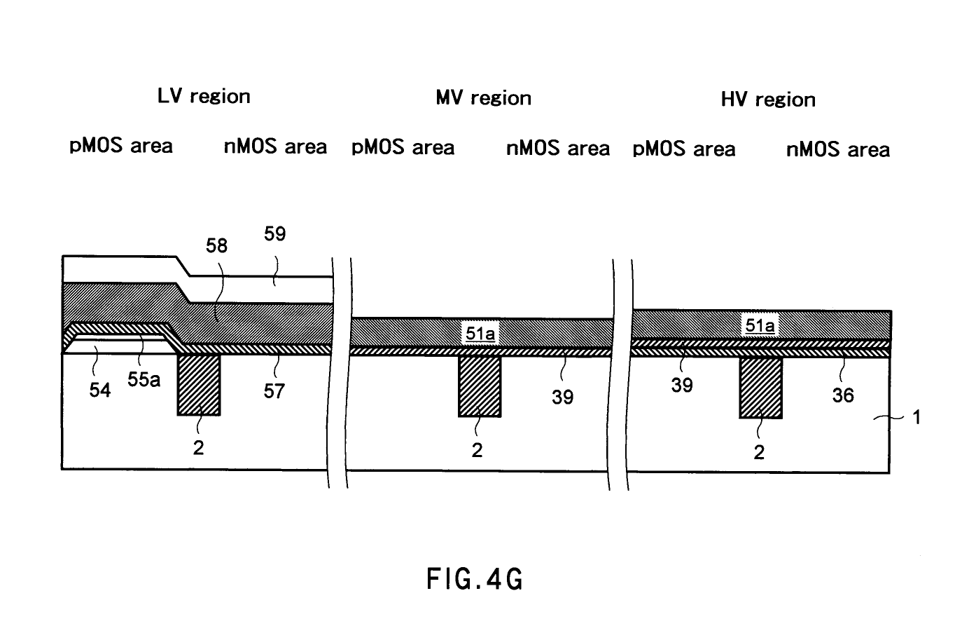

With reference to FIGS. 4A to 4G, a fourth embodiment is now described. One of differences of the present embodiment from the third embodiment is that in the present embodiment, a p-type MOSFET to which a high-k film and a metal gate electrode are applied is formed in the LV region whereas conventional p-type MOSFETs to which a silicon oxide film and polysilicon are applied are formed in the MV and HV regions.

The processes up to the process of forming the second gate insulating film 39 (FIGS. 3A to 3D) described in the third embodiment are the same as those in the present embodiment, and therefore the subsequent processes are described below.

(1) A polysilicon film 51 (not shown) is formed in each of the LV, MV and HV regions. Next, with the PMOS areas covered with resists (not shown), for example, phosphor (P) as an n-type dopant is ion-implanted into the NMOS areas, and then the resists in the PMOS areas are stripped. Next, with the NMOS areas covered with resists, for example, boron (B) as a p-type dopant is ion-implanted into the PMOS areas. Then, the resists in the NMOS areas are stripped. This causes the polysilicon films 51 to be conductive layers 51a functioning as gate electrodes. Thereafter, as shown in FIG. 4A, a silicon oxide film 52 (SiO₂) is formed in each of the LV, MV and HV regions by a CVD method.

(2) As shown in FIG. 4B, with the MV region, the HV region and the NMOS area of the LV region covered with resists 53, the silicon oxide film 52, the conductive layer 51a, the second gate insulating film 39 and the first gate insulating film 36 in the PMOS area of the LV region are removed by dry etching. Then, the resists 53 are removed.

(3) As shown in FIG. 4C, after a cleaning process is performed so as to remove a natural oxide film naturally formed on the Si substrate 1 in the PMOS area of the LV region, a SiGe film 54 is formed in the PMOS area of the LV region by selective epitaxial growth. The Ge concentration of the SiGe film 54 is, for example, 30% (Si_{0.7}Ge_{0.3}). Note that the film thickness of the SiGe film 54 is, for example, 7 nm.

(4) As shown also in FIG. 4C, a silicon film 55 is formed on the SiGe film 54 by selective epitaxial growth. Note that, to reduce the thickness of the whole gate insulating film, it is preferable that the film thickness of the silicon film 55 be such a thickness, for example, 1 nm, that all the silicon film 55 is oxidized when a third gate insulating film 57 to be described later is formed.

(5) As shown in FIG. 4D, with the MV region, the HV region and the PMOS area of the LV region covered with resists 56, the silicon oxide film 52, the conductive layer 51a, the second gate insulating film 39 and the first gate insulating film 36 in the NMOS area of the LV region are removed by dry etching. Then, the resists 56 are removed.

(6) As shown in FIG. 4E, the third gate insulating film 57 is formed in each of the LV, MV and HV regions. Used as this third gate insulating film 57 is a high-k film (for example, HfSiON). Note that when the third gate insulating film 57 is formed, at least part of the silicon film 55 is oxidized to be a silicon oxide film 55a (SiO₂). Preferably, by the third gate insulating film 57, just all the silicon film 55 is oxidized to be a silicon oxide film 55a.

(7) As shown in FIG. 4F, a metal layer 58 and a polysilicon film 59 are sequentially formed on the third gate insulating film 57 in each of the LV, MV and HV regions. Used as the material of the metal layer 58 is, for example, TaC.

(8) As shown in FIG. 4G, with only the LV region covered with a resist (not shown), the polysilicon films 59, the metal layers 58, the third gate insulating films 57 and the silicon oxide films 52 in the MV and HV regions are removed using dry etching and wet etching as appropriate. Then, the resist in the LV region is removed.

Hereafter, through the same processes as those described in the first embodiment, gates, source/drain regions and the like are formed, thereby fabricating p-type MOSFETs in the PMOS areas and n-type MOSFETs in the NMOS areas.

As described above, in the present embodiment, like the third embodiment, the first gate insulating film 36 and the second gate insulating film 39, which function as gate insulating films in the MV and HV regions, are formed. Then, the SiGe film 54 is formed in the PMOS area of the LV region, and subsequently the silicon film 55 is formed.

This can avoid oxidization of the SiGe film 54 by the process of forming gate insulating films in the MV and HV regions, and cutting of the SiGe film 54 by wet etching during removal of gate insulating films.

Thus, according to the present embodiment, like the third embodiment, the controllability of the threshold voltage of the p-type MOSFET in the LV region can further be improved.

Furthermore, according to the present embodiment, conventional type MOSFETs using non-high-k films (silicon oxide films or silicon oxynitride films) and polysilicon electrodes are formed in the MV and HV regions. Therefore, for the MV and HV regions, the commonality of design can be achieved between the LSI according to the present embodiment and the LSI made up of conventional type MOSFETs.

Hereinbefore, four embodiments have been described. While three types of p-type MOSFETs whose gate insulating films have different film thickness have been described in each embodiment, the invention is not limited to this case. the invention can be applied to a method of manufacturing a plurality of types of p-type MOSFETs having different gate insulating films. For example, the invention may be applied to manufacturing of an LSI that does not have the MV region (that is, having only the LV and HV regions), so that two types of p-type MOSFETs whose gate insulating films have different film thickness are manufactured.

While the p-type MOSFETs and the n-type MOSFETs are simultaneously formed in the above description, only the p-type MOSFETs may be formed using a manufacturing method according to the invention.

As the first gate insulating films 6 and 36 and the second gate insulating films 8 and 39 in the first to third embodiments, a high-k film may be used.

In the first and second embodiments, the SiGe film 5 is formed by selective epitaxial growth, and then successively a silicon thin film may be formed as a protective film on the SiGe film 5. This can prevent the SiGe film 5 from thermal oxidation when a gate insulating film (the first gate insulating film 6, the second gate insulating film 8 or the third gate insulating film 12 (26)) is formed. Thus, the controllability of the threshold voltage can be improved.

While silicon films are formed as protective films of the Si₁₋ₓGeₓ films (0<x<1) 5, 41 and 54 in the above description, the protective films are not limited to this. Si_{1-y}Ge_{y} films (0<y<1), in place of the silicon films, may be formed by selective epitaxial growth. In this case, the Ge concentration in the SiGe film as the protective film is preferably lower than those of the SiGe films 5, 41 and 54 (that is, y<x), and more preferably 5% or less (that is, y≦0.05).

Although additional advantages and various modification may occur to those skilled in the art based on the description given herein, the invention in its broader aspects is not limited to the individual embodiments shown and described herein. Various additions, modifications and changes may be made without departing from the spirit or scope of the general inventive concepts as defined by the appended claims and their equivalents.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

What is claimed is:

1. A method of manufacturing a semiconductor device, the method fabricating two types of field-effect transistors in a first region and a second region on a silicon substrate, respectively, the two types of field-effect transistors including gate insulating films having different film thickness, the method comprising:
forming a silicon-germanium film (Si₁₋ₓGeₓ, 0<x<1) in each of the first region and the second region;
forming a first gate insulating film on the silicon-germanium film in the first region and the second region;
removing the first gate insulating film in the first region;
forming a protective film for the silicon-germanium film, on the silicon-germanium film formed in the first region; and
forming a second gate insulating film comprising a high-k film on the protective film in the first region and on the first gate insulating film in the second region.

2. The method of manufacturing a semiconductor device according to claim 1, wherein as the protective film for the silicon-germanium film, a silicon film is formed by selective epitaxial growth.

3. The method of manufacturing a semiconductor device according to claim 2, wherein the silicon film as the protective film is formed to have such a thickness that just all the silicon film is oxidized by forming of the second gate insulating film.

4. The method of manufacturing a semiconductor device according to claim 1, wherein as the protective film for the silicon-germanium film, a silicon-germanium film (Si_{1-y}Ge_{y}, 0<y<1, y<x) is formed by selective epitaxial growth.

5. A method of manufacturing a semiconductor device, the method fabricating three types of field-effect transistors in a first region, a second region and a third region on a silicon substrate, respectively, the three types of field-effect transistors including gate insulating films having different film thickness, the method comprising:
forming a silicon-germanium film (Si₁₋ₓGeₓ, 0<x<1) in each of the first region, the second region and the third region;
forming a first gate insulating film on the silicon-germanium film in the first region, the second region and the third region;
removing the first gate insulating film in the second region;
forming a second gate insulating film on the first gate insulating film in the first region and the third region and on the silicon-germanium film in the second region;
removing the first gate insulating film and the second gate insulating film in the first region;
forming a protective film for the silicon-germanium film on the silicon-germanium film in the first region;
forming a third gate insulating film comprising a high-k film on the protective film in the first region and on the second gate insulating film in the second region and the third region; and
forming a metal layer on the third gate insulating film in the first region, the second region and the third region.

6. The method of manufacturing a semiconductor device according to claim 5, wherein as the protective film for the silicon-germanium film, a silicon film is formed by selective epitaxial growth.

7. The method of manufacturing a semiconductor device according to claim 6, wherein the silicon film as the protective film is formed to have such a thickness that just all the silicon film is oxidized when the third gate insulating film is formed.

8. The method of manufacturing a semiconductor device according to claim 5, wherein as the protective film for the silicon-germanium film, a silicon-germanium film (Si_{1-y}Ge_{y}, 0<y<1, y<x) is formed by selective epitaxial growth.

9. A method of manufacturing a semiconductor device, the method fabricating two types of field-effect transistors in a first region and a second region on a silicon substrate, respectively, the two types of field-effect transistors including gate insulating films having different film thickness, the method comprising:
forming a first gate insulating film in the first region and the second region;
removing the first gate insulating film in the first region;
successively forming a silicon-germanium film (Si₁₋ₓGeₓ, 0<x<1) and a protective film for the silicon-germanium film on the silicon-germanium film, in the first region; and
forming a second gate insulating film comprising a high-k film on the protective film in the first region and on the first gate insulating film in the second region.

10. The method of manufacturing a semiconductor device according to claim 9, wherein as the protective film for the silicon-germanium film, a silicon film is formed by selective epitaxial growth.

11. The method of manufacturing a semiconductor device according to claim 10, wherein the silicon film as the protective film is formed to have such a thickness that just all the silicon film is oxidized when the second gate insulating film is formed.

12. The method of manufacturing a semiconductor device according to claim 9, wherein as the protective film for the silicon-germanium film, a silicon-germanium film (Si_{1-y}Ge_{y}, 0<y<1, y<x) is formed by selective epitaxial growth.

13. A method of manufacturing a semiconductor device, the method fabricating three types of field-effect transistors in a first region, a second region and a third region on a silicon substrate, respectively, the three types of field-effect transistors including gate insulating films having different film thickness, the method comprising:
forming a first gate insulating film in the first region, the second region and the third region;
removing the first gate insulating film in the second region;
forming a second gate insulating film on the first gate insulating film in the first region and the third region, and in the second region;
removing the first gate insulating film and the second gate insulating film in the first region;
successively forming in the first region a silicon-germanium film (Si₁₋ₓGeₓ, 0<x<1) and a protective film for the silicon-germanium film on the silicon-germanium film;
forming a third gate insulating film comprising a high-k film on the protective film in the first region and on the second gate insulating film in the second region and the third region; and
forming a metal layer on the third gate insulating film in the first region, the second region and the third region.

14. The method of manufacturing a semiconductor device according to claim 13, wherein as the protective film for the silicon-germanium film, a silicon film is formed by selective epitaxial growth.

15. The method of manufacturing a semiconductor device according to claim 14, wherein the silicon film as the protective film is formed to have such a thickness that just all the silicon film is oxidized when the third gate insulating film is formed.

16. The method of manufacturing a semiconductor device according to claim 13, wherein as the protective film for the silicon-germanium film, a silicon-germanium film (Si_{1-y}Ge_{y}, 0<y<1, y<x) is formed by selective epitaxial growth.
